(19) United States
(12) Patent Application Publication
(10) Pub. No.: US 2025/0331290 A1
(43) Pub. Date: Oct. 23, 2025

(54) SILICON CARBIDE SEMICONDUCTOR DEVICE, POWER MODULE DEVICE, POWER CONVERTER, AND MOBILE BODY

(71) Applicant: Mitsubishi Electric Corporation, Tokyo (JP)

(72) Inventors: Yoichi HIRONAKA, Tokyo (JP); Katsutoshi SUGAWARA, Tokyo (JP); Kenji HATORI, Tokyo (JP); Shiro HINO, Tokyo (JP)

(73) Assignee: Mitsubishi Electric Corporation, Tokyo (JP)

(21) Appl. No.: 18/870,271

(22) PCT Filed: Aug. 3, 2022
(86) PCT No.: PCT/JP2022/029729

§ 371 Date: Nov. 27, 2024

(51) Int. Cl. H10D 84/00; H10D 62/832

(52) U.S. Cl. CPC H10D 84/146; H10D 62/8325

(57) ABSTRACT

The silicon carbide semiconductor device includes a semiconductor layer of a first conductivity type which is provided with an active region which includes a unit cell region including a Schottky barrier diode region and a MOSFET region, and a surge energization region. The surge energization region includes a Schottky barrier diode replacement region in which the first conductivity type of the Schottky barrier diode region is replaced with a second conductivity type. The area ratio of the Schottky barrier diode replacement region in the active region is not lower than 0.01% and lower than the area ratio of the Schottky barrier diode region in the active region in a case where the Schottky barrier diode region is not replaced with the Schottky barrier diode replacement region.

### TECHNICAL FIELD

The present disclosure relates to a silicon carbide semiconductor device, a power module device, a power converter, and a mobile body.

### BACKGROUND ART

Well known is a problem that a crystal defect such as a stacking fault or the like occurs in a crystal and a forward voltage is thereby shifted when a forward current, i.e., a bipolar current is continuously carried in a pn diode provided in a semiconductor layer formed of silicon carbide (SiC). It is thought that this is because the crystal defect such as the stacking fault or the like which is a plane defect is extended with a basal plane dislocation or the like existing in the semiconductor layer formed of silicon carbide, as a starting point due to a recombination energy generated when minority carriers injected through the pn diode are recombined with majority carriers. Since this crystal defect inhibits a flow of currents, when the crystal defect is extended, currents are reduced and the forward voltage increases, and this causes degradation in the reliability of a silicon carbide semiconductor device.

Such an increase in the forward voltage also occurs in a vertical MOSFET (Metal Oxide Semiconductor Field Effect transistor) using silicon carbide. The vertical MOSFET includes a body diode which is a parasitic pn diode between a source and a drain, and when the forward current is carried in the body diode, this causes degradation in the reliability in the vertical MOSFET, like in the pn diode. For this reason, when the body diode of a SiC-MOSFET is used as a freewheeling diode of the MOSFET, degradation in the MOSFET characteristics sometimes occurs.

As a structure for solving the above-described problem of reliability due to energization of the forward current to the parasitic pn diode, proposed is a structure in which a unipolar diode is embedded as the freewheeling diode in the silicon carbide semiconductor device which is a unipolar transistor such as the MOSFET or the like. In Patent Documents 1 and 2, for example, proposed is a structure in which a Schottky barrier diode (SBD) which is a unipolar diode is embedded in a unit cell of the MOSFET.

In the silicon carbide semiconductor device formed of a unipolar transistor in which a unipolar diode is embedded, since the bipolar current of the body diode, i.e., the parasitic pn diode can be reduced during a reflux operation, it is possible to suppress degradation of characteristics of the transistor.

### PRIOR ART DOCUMENTS

### Patent Document(s)

[Patent Document 1] Japanese Patent Application Laid Open Gazette No. 2003-017701
[Patent Document 2] WO 2014/038110

### SUMMARY

### Problem to be Solved by the Invention

The pn diode which is a bipolar diode, however, becomes low resistance due to modulation of conductivity by a bipolar operation, but the SBD which is the unipolar diode has a relatively high resistance. For this reason, the generated energy during energization of the SBD is higher than that during energization of the body diode which is the pn diode.

As a result, in the silicon carbide semiconductor device in which the above-described SBD is embedded, the generated energy density is high when the SBD is energized by a surge current such as a fault current or the like, and large heat generation occurs in the SBD. For this reason, there arises a problem that a surge capability which is breakage tolerance for the surge current becomes lower.

Then, the present disclosure is intended to solve the above-described problem, and it is an object of the present disclosure to provide a technique for making it possible to increase surge capability in a silicon carbide semiconductor device in which an SBD is embedded.

### Means to Solve the Problem

The present disclosure is intended for a silicon carbide semiconductor device, and the silicon carbide semiconductor device includes a semiconductor layer of a first conductivity type which is provided with an active region which includes a unit cell region including a Schottky barrier diode region and a MOSFET region, and a surge energization region, and in the silicon carbide semiconductor device, the surge energization region includes a Schottky barrier diode replacement region in which the first conductivity type of the Schottky barrier diode region is replaced with a second conductivity type, and an area ratio of the Schottky barrier diode replacement region in the active region is not lower than 0.01% and lower than an area ratio of the Schottky barrier diode region in the active region in a case where the Schottky barrier diode region is not replaced with the Schottky barrier diode replacement region.

### Effects of the Invention

According to the present disclosure, during a long reflux operation by a surge current such as a fault current or the like, in a chain reaction with an operation of a pn diode formed in the Schottky barrier diode replacement region, the body diode in a plane of the active region is operated earlier, as compared with a case of not being replaced with the Schottky barrier diode replacement region, and the generated energy density is reduced, and it is therefore possible to increase surge capability.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 is a plan view showing a structure of a silicon carbide semiconductor device in accordance with a first preferred embodiment;

FIG. 2 is a plan view showing the structure of the silicon carbide semiconductor device in accordance with the first preferred embodiment;

FIG. 3 is a schematic cross-sectional view showing the structure of the silicon carbide semiconductor device in accordance with the first preferred embodiment;

FIG. 4 is a schematic plan view showing the structure of the silicon carbide semiconductor device in accordance with the first preferred embodiment;

FIG. 5 is a schematic plan view showing the structure of the silicon carbide semiconductor device in accordance with the first preferred embodiment;

FIG. 6 is a schematic cross-sectional view showing the structure of the silicon carbide semiconductor device in accordance with the first preferred embodiment;

FIG. 7 is a plan view showing the structure of the silicon carbide semiconductor device in accordance with the first preferred embodiment;

FIG. 8 is a schematic cross-sectional view showing the structure of the silicon carbide semiconductor device in accordance with the first preferred embodiment;

FIG. 9 is a schematic cross-sectional view showing the structure of the silicon carbide semiconductor device in accordance with the first preferred embodiment;

FIG. 10 is a schematic cross-sectional view for explaining a method of manufacturing the silicon carbide semiconductor device in accordance with the first preferred embodiment;

FIG. 11 is a schematic cross-sectional view for explaining the method of manufacturing the silicon carbide semiconductor device in accordance with the first preferred embodiment;

FIG. 12 is a schematic cross-sectional view for explaining the method of manufacturing the silicon carbide semiconductor device in accordance with the first preferred embodiment;

FIG. 13 is a schematic cross-sectional view for explaining the method of manufacturing the silicon carbide semiconductor device in accordance with the first preferred embodiment;

FIG. 14 is a schematic cross-sectional view for explaining the method of manufacturing the silicon carbide semiconductor device in accordance with the first preferred embodiment;

FIG. 15 is a schematic cross-sectional view for explaining the method of manufacturing the silicon carbide semiconductor device in accordance with the first preferred embodiment;

FIG. 16 is a schematic cross-sectional view for explaining the method of manufacturing the silicon carbide semiconductor device in accordance with the first preferred embodiment;

FIG. 17 is a schematic cross-sectional view for explaining the method of manufacturing the silicon carbide semiconductor device in accordance with the first preferred embodiment;

FIG. 18 is a view showing a simulation result of the silicon carbide semiconductor device in accordance with the first preferred embodiment;

FIG. 19 is a graph for explaining switching of energization in the silicon carbide semiconductor device in accordance with the first preferred embodiment;

FIG. 20 is a graph for explaining switching of energization in the silicon carbide semiconductor device in accordance with the first preferred embodiment;

FIG. 21 is a schematic cross-sectional view showing a structure of a silicon carbide semiconductor device in accordance with a second preferred embodiment;

FIG. 22 is a plan view showing a structure of a silicon carbide semiconductor device in accordance with a third preferred embodiment;

FIG. 23 is a plan view showing the structure of the silicon carbide semiconductor device in accordance with the third preferred embodiment;

FIG. 24 is a schematic cross-sectional view showing the structure of the silicon carbide semiconductor device in accordance with the third preferred embodiment;

FIG. 25 is a schematic cross-sectional view showing the structure of the silicon carbide semiconductor device in accordance with the third preferred embodiment;

FIG. 26 is a schematic cross-sectional view for explaining a method of manufacturing the silicon carbide semiconductor device in accordance with the third preferred embodiment;

FIG. 27 is a schematic cross-sectional view for explaining the method of manufacturing the silicon carbide semiconductor device in accordance with the third preferred embodiment;

FIG. 28 is a schematic cross-sectional view for explaining the method of manufacturing the silicon carbide semiconductor device in accordance with the third preferred embodiment;

FIG. 29 is a schematic cross-sectional view for explaining the method of manufacturing the silicon carbide semiconductor device in accordance with the third preferred embodiment;

FIG. 30 is a schematic cross-sectional view for explaining the method of manufacturing the silicon carbide semiconductor device in accordance with the third preferred embodiment;

FIG. 31 is a schematic cross-sectional view for explaining the method of manufacturing the silicon carbide semiconductor device in accordance with the third preferred embodiment;

FIG. 32 is a block diagram showing a structure of a power module device in accordance with a fourth preferred embodiment;

FIG. 33 is a block diagram showing a structure of a power converter in accordance with a fifth preferred embodiment; and

FIG. 34 is a view showing a structure of a mobile body in accordance with a sixth preferred embodiment.

### DESCRIPTION OF EMBODIMENT(S)

In the following description, “n” and “p” each represent a conductivity type of semiconductor. In the present disclosure, description will be made assuming that a first conductivity type is n type and a second conductivity type is p type, but it may be assumed that the first conductivity type is p type and the second conductivity type is n type.

Hereinafter, the preferred embodiments of the present disclosure will be described with reference to attached figures. Further, figures are schematically shown, and the correlation in the size and position of respective images shown in different figures is not always represented accurately but can be changed as appropriate. Furthermore, in the following description, identical constituent elements are represented by the same reference signs and each have the same or similar name and function. Therefore, detailed description thereof will be sometimes omitted.

Hereinafter, description will be made on a case where a silicon carbide semiconductor device is an SBD-embedded SiC MOSFET. The silicon carbide semiconductor device can perform a stable operation under a high temperature and a high voltage and increase in the switching speed, as compared with a silicon semiconductor device.

### The First Preferred Embodiment

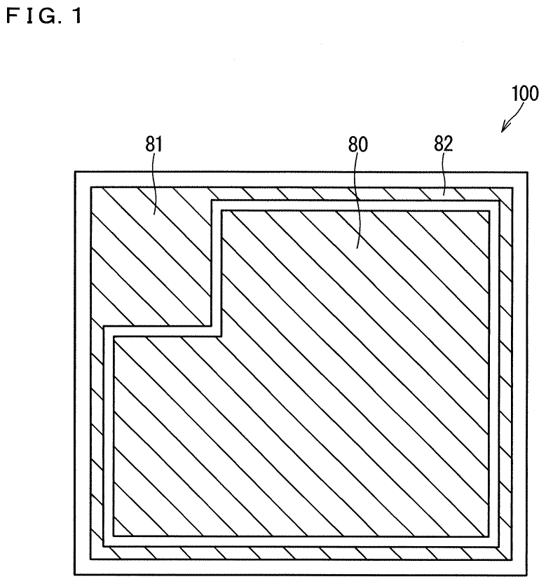

FIG. 1 is a plan view, viewed from an upper surface, showing a structure of a silicon carbide semiconductor device 100 in accordance with the first preferred embodiment. The silicon carbide semiconductor device 100 in accordance with the first preferred embodiment is a planar-type silicon carbide semiconductor device. In FIG. 1, a gate pad 81 is formed on part of the upper surface of the silicon carbide semiconductor device 100, and a source electrode 80 is formed adjacent thereto. Further, a gate wiring 82 extending from the gate pad 81 is formed.

### (1) Planar Stripe Structure

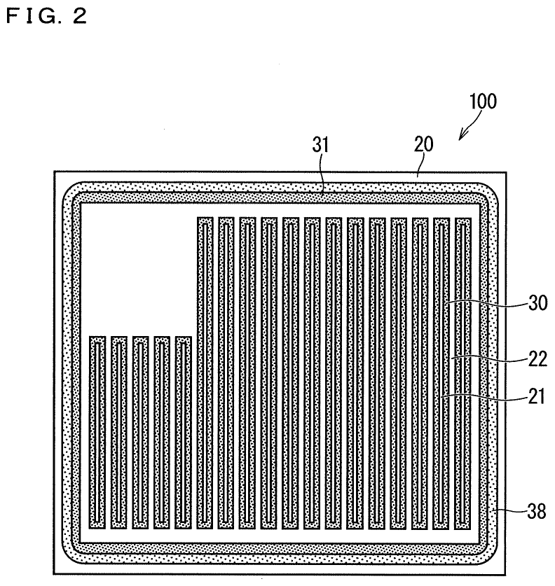

FIG. 2 is a plan view showing a silicon carbide layer of the silicon carbide semiconductor device 100 in accordance with the first preferred embodiment, viewed from the upper surface. This FIG. 2 corresponds to a plan view of FIG. 1 except the source electrode 80, the gate pad 81, and the gate wiring 82. In the silicon carbide semiconductor device 100, provided is an active region including a unit cell region and a surge energization region. In FIG. 2, the unit cell regions each including an SBD region (Schottky barrier diode region) and MOSFET regions provided on both sides of the SBD region, sandwiching the SBD region, are provided, being aligned in stripes. The structure of the silicon carbide semiconductor device 100 in which such unit cell regions are provided is referred to as a “stripe” structure.

In FIG. 2, the unit cell regions each including an n-type first separation region 21 which substantially corresponds to the SBD region and a p-type first well region 30 which substantially corresponds to the MOSFET region are repeatedly arranged in one direction in a plan view. A region including the unit cell region in which such an SBD-embedded MOSFET is formed and a later-described surge energization region is referred to as an active region. A region which is an outer peripheral region of the active region, including a formation region of the gate pad 81 on which a p-type second well region 31 and the like are formed, is referred to as a terminal region.

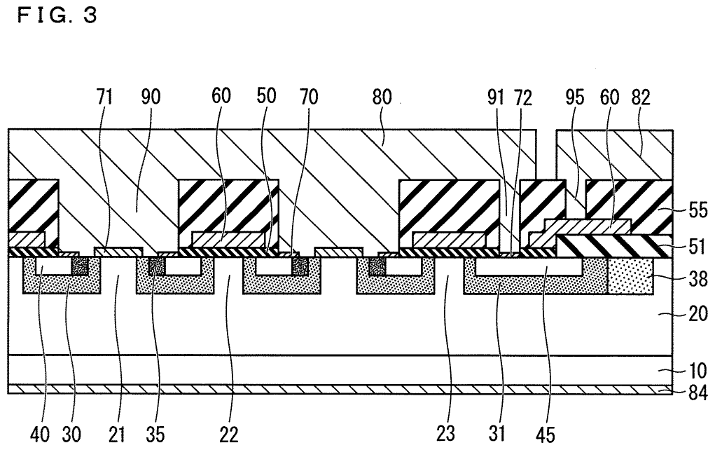

FIG. 3 is a schematic cross-sectional view showing a schematic structure from the source electrode 80 of FIG. 1 to the gate wiring 82 in an outer peripheral portion of the silicon carbide semiconductor device 100, viewed from a longitudinal direction of the stripe-shaped unit cell regions.

In the silicon carbide semiconductor device 100 shown in FIG. 3, a drift layer 20 formed of n-type silicon carbide is formed on a surface of a semiconductor substrate 10 formed of low-resistance n-type silicon carbide. In the present first preferred embodiment, a semiconductor layer on which the active region is provided is the drift layer 20 on the semiconductor substrate 10 but may be the semiconductor substrate 10, In a surface layer portion of the drift layer 20 positioned substantially corresponding to the region in which the gate wiring 82 is provided as described with reference to FIG. 1, as shown in the cross-sectional view of FIG. 3, the second well region 31 formed of p-type silicon carbide is provided.

In the surface layer portion of the drift layer 20 in the active region which is a region below the source electrode 80 described with reference to FIG. 1, the first well region 30 formed of p-type silicon carbide is provided. As shown in FIG. 2, the first well regions 30 are formed in stripes in a plan view. One well region obtained by connecting a plurality of first well regions 30 to one another may be provided, or a plurality of separated first well regions 30 may be provided.

As shown in FIG. 3, in a surface layer portion of the first well region 30, a source region 40 formed of n-type silicon carbide is formed at a position by a certain distance inward from an outer periphery of the first well region 30.

On an end side of the source region 40 in the surface layer portion of the first well region 30, a contact region 35 formed of low-resistance p-type silicon carbide is formed. Between the adjacent contact regions 35, the first separation region 21 formed of silicon carbide, penetrating the first well region 30, is formed. As shown in FIG. 2, the first separation regions 21 are formed in stripes. The conductivity type of the first separation region 21 is n type which is the same as that of the drift layer 20, and the n-type impurity concentration of the first separation region 21 may be equal to that of the drift layer 20, or may be higher or lower than that of the drift layer 20.

As shown in FIG. 3, on a surface side of the first separation region 21, stripe-shaped Schottky electrodes 71 in a plan view, each of which is Schottky-connected to the first separation region 21, are formed. It is preferable that the Schottky electrode 71 should be formed in a region including the first separation region 21 corresponding thereto in a plan view.

On a surface of the source region 40, an ohmic electrode 70 is formed. The source electrode 80 connected to the ohmic electrode 70, the Schottky electrode 71, and the contact region 35 is formed thereon. The first well region 30 can easily give and receive electrons or positive holes to/from the ohmic electrode 70 through the low-resistance contact region 35.

In a region other than the first separation region 21 in the region between the adjacent first well regions 30, a second separation region 22 formed of n-type silicon carbide is formed. The conductivity type of the second separation region 22 is n type which is the same as that of the drift layer 20, and the n-type impurity concentration of the second separation region 22 may be equal to that of the drift layer 20, or may be higher or lower than that of the drift layer 20.

On surfaces of the adjacent first well regions 30, the second separation region 22 therebetween, and the respective source regions 40 inside these first well regions 30, a gate insulating film 50 formed of, for example, silicon oxide is selectively formed. On at least the gate insulating film 50 on an upper side of the first well region 30, a gate electrode 60 formed of, for example, polycrystalline silicon is formed. A surface layer portion of the first well region 30 facing the gate electrode 60 with the gate insulating film 50 interposed therebetween is referred to as a “channel region”.

On an outer side of the first well region 30 in an outermost perimeter of the silicon carbide semiconductor device 100, the second well region 31 is formed, and between the first well region 30 and the second well region 31, a third separation region 23 formed of silicon carbide is formed. The conductivity type of the third separation region 23 is n type which is the same as that of the drift layer 20, and the n-type impurity concentration of the third separation region 23 may be equal to that of the drift layer 20, or may be higher or lower than that of the drift layer 20.

The gate insulating film 50 is selectively formed on the second well region 31, like on the first well region 30, and on the gate insulating film 50, formed is the gate electrode 60 electrically connected to the gate electrode 60 formed on the first well region 30.

In a region at a certain ratio of an upper layer portion of the second well region 31, formed is a silicon carbide conductive layer 45 formed of silicon carbide, having an n-type impurity concentration higher than that of the drift layer 20 and a low resistance. The silicon carbide conductive layer 45 has a sheet resistance lower than that of the second well region 31 and forms a pn junction with the p-type second well region 31. The silicon carbide conductive layer 45 is formed, for example, across the width which is a half or more of the width in a cross (transverse) sectional direction of the second well region 31. A portion where the silicon carbide conductive layer 45 is formed at the width which is a half or more of the width in the cross sectional direction of the second well region 31 does not necessarily need to be provided in all the cross sections but may be provided in some of the cross sections.

Between the gate electrode 60 and the source electrode 80, formed is an interlayer insulating film 55 formed of, for example, silicon oxide. The gate electrode 60 and the gate wiring 82 above the second well region 31 are connected to each other through a gate contact hole 95 formed in the interlayer insulating film 55. Further, on an outer peripheral side of the second well region 31, i.e., on the opposite side of the first well region 30, formed is a JTE region 38 formed of p-type silicon carbide. The impurity concentration of the JTE region 38 is lower than that of the second well region 31. An FLR (Field Limiting Ring) may be formed, instead of the JTE region 38. Furthermore, a combination of the JTE region 38 and the FLR may be formed.

On the second well region 31 and the silicon carbide conductive layer 45, a field insulating film 51 having a film thickness larger than that of the gate insulating film 50 or the gate insulating film 50 is formed. In part of the gate insulating film 50 or the field insulating film 51 on a surface of the silicon carbide conductive layer 45, an opening, i.e., a terminal region contact hole 91 is formed. The silicon carbide conductive layer 45 and the source electrode 80 are ohmic-connected to each other through an ohmic electrode 72 positioned at a terminal portion on the lower side of the terminal region contact hole 91.

The terminal region contact hole 91 penetrates the gate insulating film 50 or the field insulating film 51 and the interlayer insulating film 55, to thereby make an ohmic connection between the silicon carbide conductive layer 45 and the source electrode 80 but not connect the second well region 31 and the source electrode 80. Further, the width of the silicon carbide conductive layer 45 is larger than the diameter or the width of the terminal region contact hole 91. In the present first preferred embodiment, the second well region 31 is not directly ohmic-connected to the source electrode 80.

In the active region, the ohmic electrode 70, the Schottky electrode 71, and the contact region 35 are connected to the source electrode 80 on the interlayer insulating film 55 through an active region contact hole 90 penetrating the interlayer insulating film 55 and the gate insulating film 50.

On a back-surface side of the semiconductor substrate 10, formed is a drain electrode 84.

In a case where the plane orientation of a first main surface of the semiconductor substrate 10 is a (0001) plane having an off angle in a <11-20> direction, an extension direction of the stripe-shaped first well regions 30 may be parallel to the <11-20> direction which is an off-direction or may be parallel to an orthogonal direction of the off-direction.

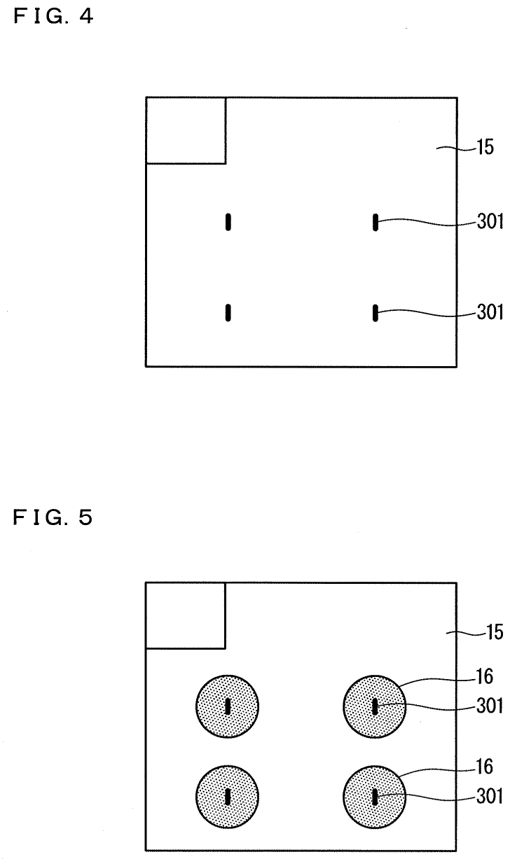

FIG. 4 is a schematic plan view more schematically showing the structure of the silicon carbide layer shown in FIG. 2. The active region 15 includes a surge energization region 301 as well as the above-described unit cell region.

The surge energization region 301 does not have the first separation region 21 which is in contact with the Schottky electrode 71, and is defined, for example, as a region whose circumference is surrounded by the first separation region 21. Herein, “being surrounded” is not necessarily limited to “being surrounded by a continuous first separation region 21” but includes “being adjacent to a plurality of first separation regions 21 periodically arranged, being separated at end portions in the extension direction of the stripes”, as shown in the plan view of FIG. 2. In other words, the surge energization region 301 is a region whose circumference is adjacent to, and preferably surrounded by the first separation region 21 connected to the Schottky electrode 71 in a plan view, in the active region 15 covered with the source electrode 80.

The area of the surge energization region 301 is sufficiently smaller than that of the entire active region 15, and the surge energization region 301 is provided in the active region 15. Further, like the unit cell region, the surge energization region 301 is covered with the source electrode 80. From these points, the surge energization region 301 is clearly distinguished from the second well region 31 formed below the gate pad 81 around the active region 15 and having a relatively large area.

The surge energization region 301 is formed inside at least one unit cell region in a chip. In a case where the surge energization region 301 is formed inside two or more unit cell regions, it is preferable that the surge energization region 301 should be formed, being dispersed in the chip in a plan view.

As described later, the surge energization region 301 includes a Schottky barrier diode replacement region 302 in which the n-type of the SBD region in the unit cell region is replaced with the p-type, and the p-type Schottky barrier diode replacement region 302 cooperates with the n-type drift layer 20, to thereby have a function of the pn diode. During a reflux operation where a current is carried for an energization time which is sufficiently long, i.e., 1 to 10 msec or the like, in the silicon carbide semiconductor device 100, a body diode of the unit cell region is operated in a chain reaction with the operation of the pn diode. The body diode herein includes a parasitic pn diode which is a freewheeling diode of the MOSFET.

In the present first preferred embodiment, the area ratio of the p-type Schottky barrier diode replacement region 302 in the active region 15 in a plan view is not lower than 0.01% and lower than the area ratio of the SBD region, not being replaced with the Schottky barrier diode replacement region 302, in the active region 15, and more preferably not lower than 0.01% and not higher than 5%.

In a case where the area ratio of the Schottky barrier diode replacement region 302 is equal to that of the SBD region, not being replaced with the Schottky barrier diode replacement region 302, there is no SBD in the plane of the active region 15 and the function as the SBD-embedded MOSFET is lost.

Further, as the ratio of the Schottky barrier diode replacement region 302 in the plane becomes smaller, an effect on original electrical characteristics becomes smaller, and then it is expected to increase the efficiency (reduce the loss) of power conversion.

In the silicon carbide semiconductor device 100 in accordance with the present first preferred embodiment, during the above-described reflux operation, the area ratio of a body diode chain operation region 16 which is a region in which the body diode operates in a chain reaction, in the active region 15, increases as the energization time becomes longer and in the end, the body diode operates entirely in the active region 15. FIG. 5 is a view showing an example of such a body diode chain operation region 16. The speed until the body diode chain operation region 16 spreads entirely in the active region 15 during the above-described reflux operation is adjusted by adjusting the size of each surge energization region 301 and the number of surge energization regions 301.

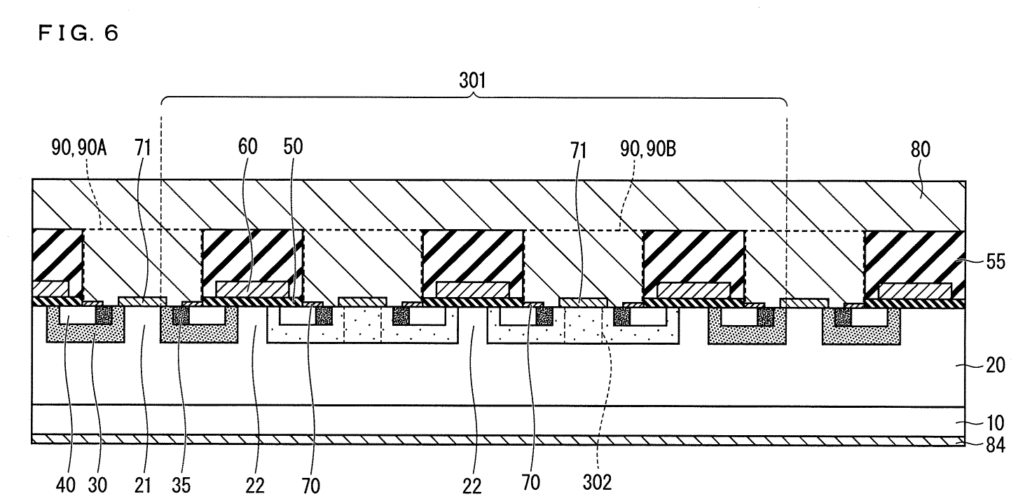

FIG. 6 is a schematic cross-sectional view showing a schematic structure of the surge energization region 301 and the active region contact hole 90, viewed from the longitudinal direction of the stripe-shaped unit cell regions.

On an inner side of the surge energization region 301, in the surface layer portion of the drift layer 20, one or more Schottky barrier diode replacement regions 302 formed of p-type silicon carbide are formed. The Schottky barrier diode replacement region 302 is provided between the Schottky electrode 71 and the drift layer 20, and the pn junction is thereby interposed at some midpoint of a conduction path between the source electrode 80 and the drain electrode 84. In other words, the Schottky electrode 71 is not connected to the n-type silicon carbide layer such as the n-type first separation region 21 or the like having the same n-type as the drift layer 20, and the Schottky electrode 71 and the drift layer 20 are separated by the Schottky barrier diode replacement region 302. Further, “being connected” herein refers to a state where the Schottky current can flow in a chip cross-sectional direction without the pn junction interposed at some midpoint.

In the present first preferred embodiment, the Schottky barrier diode replacement region 302 is the p-type region in which the first separation region 21 sandwiched between the adjacent first well regions 30 is replaced. The Schottky barrier diode replacement region 302 is formed below each of the Schottky electrodes 71 formed periodically. At that time, the first well region 30 adjacent to the Schottky barrier diode replacement region 302 is one p-type region. In such a layout, the width of the Schottky barrier diode replacement region 302 and the first well region 30 adjacent thereto inevitability becomes larger than the width of the first well region 30. Two merits (advantages) of this layout will be exemplarily shown below.

The first merit (advantage) is that the gate electrode 60 and the active region contact hole 90 inside the surge energization region 301 can be formed at the same pitch as that in a surrounding region. Since the gate electrode 60 and the active region contact hole 90 can be thereby arranged at regular intervals entirely inside the chip, it is possible to increase the uniformity of processing. Further, since it is not necessary to interrupt or branch the gate electrode 60 and the active region contact hole 90 at an end portion of the surge energization region 301 in the extension direction of the stripe, it is possible to further increase the uniformity of processing.

The second merit (advantage) is that the gate electrode 60 can be so formed as to penetrate the surge energization region 301 in a plan view. This causes an effect of preventing propagation of a gate potential from being interrupted by the surge energization region 301. Especially in the stripe structure, when the gate potential is interrupted by the surge energization region 301, the gate potential cannot be propagated from there onward, and a region not having the function of the MOSFET is thereby generated and this causes a demerit (disadvantage) that the chip area cannot be efficiently used. Since the propagation of the gate potential is not interrupted by the surge energization region 301, this demerit (disadvantage) can be reduced. Further, since a delay in the propagation of the gate potential in the present structure is smaller than that in a structure in which the gate electrode pattern is so formed as to bypass the surge energization region 301, it is possible to produce effects of achieving high-speed switching and of suppressing local concentration of the switching current.

Herein, the active region contact hole 90 formed above the Schottky barrier diode replacement region 302 is referred to as an active region second contact hole 90B and the active region contact hole 90 other than the above-described contact hole is referred to as an active region first contact hole 90A. The source electrode 80 is in contact with each of the source region 40 and the first separation region 21 through the active region first contact hole 90A while the source electrode 80 is in contact with the p-type Schottky barrier diode replacement region 302 through the active region second contact hole 90B. For this reason, a pn diode which is formed of the pn junction between the Schottky barrier diode replacement region 302 and the drift layer 20 and carries a current in a thickness direction of the chip is formed at a position separated from the SBD.

In the present first preferred embodiment, inside the surge energization region 301, the second separation region 22 is provided between the adjacent two Schottky barrier diode replacement regions 302 or between the Schottky barrier diode replacement region 302 and the first well region 30. The source region 40 is formed at a certain distance inward away from the end portion in the surface layer of the Schottky barrier diode replacement region 302, and the gate insulating film 50 and the gate electrode 60 are formed in a region from the second separation region 22 to the source region 40. In the present first preferred embodiment, on an inner side of the Schottky barrier diode replacement region 302, formed is a channel structure like the MOSFET region of the active region 15, and the surge energization region 301 also has the function of the MOSFET.

In the channel structure, a separation distance between the source region 40 and the second separation region 22 is referred to as a channel length. It is preferable that the channel length formed in the surge energization region 301 should be equal to or longer than that formed in the MOSFET region of the active region 15. Further, when the channel length formed in the surge energization region 301 is made too short, a current flows at a low gate voltage by a short channel effect in the surge energization region 301, and as a result, a threshold voltage of the entire chip is reduced and this makes it easier to cause a wrong operation of the device. On the other hand, when the channel length formed in the surge energization region 301 is made too long, a channel current in the surge energization region 301 is reduced, and a later-described effect to be produced by the channel current becomes harder to produce. For these reasons, it is preferable that the channel length formed in the surge energization region 301 should be equal to that formed in the MOSFET region of the active region 15.

For the same reasons, it is preferable that the impurity concentration of the channel formed in the surge energization region 301 should be equal to that formed in the MOSFET region of the active region 15. Additionally, it is preferable that the film thickness of the gate insulating film 50 in the surge energization region 301 should be equal to that of the gate insulating film 50 in the MOSFET region of the active region 15. With such a structure, it is possible to prevent a gate breakdown voltage of the Schottky barrier diode replacement region 302 from being reduced and prevent the channel current from being reduced, with respect to the MOSFET region.

### (2) Planar Lattice Structure

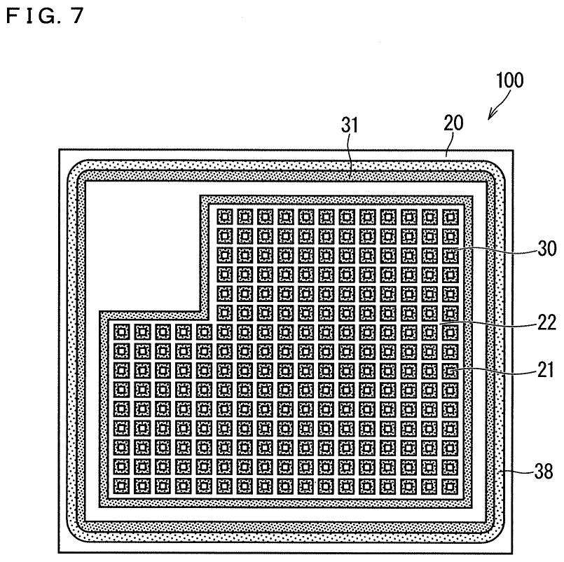

FIG. 7 is a plan view showing another structure of the silicon carbide semiconductor device 100 in accordance with the first preferred embodiment, viewed from the upper surface, and corresponds to the plan view of FIG. 2. In the silicon carbide semiconductor device 100 shown in FIG. 7, the unit cell regions each including the SBD region and the MOSFET region surrounding the SBD region are repeatedly arranged both in a longitudinal direction and in a transverse direction in a plan view. The structure of the silicon carbide semiconductor device 100 in which such unit cell regions are provided is referred to as a “lattice” structure.

In FIG. 7, the unit cell regions each including the n-type first separation region 21 which substantially corresponds to the SBD region and the p-type first well region 30 which substantially corresponds to the MOSFET region are repeatedly arranged both in the longitudinal direction and in the transverse direction in a plan view. A region including the unit cell region in which such an SBD-embedded MOSFET is formed and the surge energization region is referred to as the active region. A region which is an outer peripheral region of the active region, including the formation region of the gate pad 81 on which the p-type second well region 31 and the like are formed, is referred to as the terminal region.

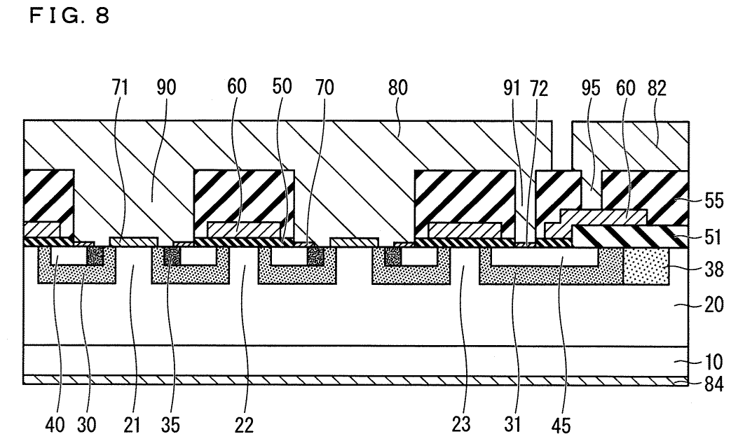

FIG. 8 is a schematic cross-sectional view showing a schematic structure from the source electrode 80 of FIG. 1 to the gate wiring 82 in the outer peripheral portion of the silicon carbide semiconductor device 100.

In the silicon carbide semiconductor device 100 shown in FIG. 8, the drift layer 20 formed of n-type silicon carbide is formed on the surface of the semiconductor substrate 10 formed of low-resistance n-type silicon carbide. In the surface layer portion of the drift layer 20 positioned substantially corresponding to the region in which the gate wiring 82 is provided as described with reference to FIG. 1, as shown in the cross-sectional view of FIG. 8, the second well region 31 formed of p-type silicon carbide is provided.

In the surface layer portion of the drift layer 20 in the active region which is a region below the source electrode 80 described with reference to FIG. 1, a plurality of first well regions 30 each formed of p-type silicon carbide are provided.

In the surface layer portion of the first well region 30, the source region 40 formed of n-type silicon carbide is formed at a position by a certain distance inward from the outer periphery of the first well region 30.

On an end side of the source region 40 in the surface layer portion of the first well region 30, the contact region 35 formed of low-resistance p-type silicon carbide is formed. Between the adjacent contact regions 35, the first separation region 21 formed of silicon carbide, penetrating the first well region 30, is formed. The conductivity type of the first separation region 21 is n type which is the same as that of the drift layer 20, and the n-type impurity concentration of the first separation region 21 may be equal to that of the drift layer 20, or may be higher or lower than that of the drift layer 20.

On the surface side of the first separation region 21, formed is the Schottky electrode 71 which is Schottky-connected to the first separation region 21. It is preferable that the Schottky electrode 71 should be formed in the region including the first separation region 21 corresponding thereto in a plan view.

On the surface of the source region 40, the ohmic electrode 70 is formed. The source electrode 80 connected to the ohmic electrode 70, the Schottky electrode 71, and the contact region 35 is formed thereon. The first well region 30 can easily give and receive electrons or positive holes to/from the ohmic electrode 70 through the low-resistance contact region 35.

In a region other than the first separation region 21 in the region between the adjacent first well regions 30, the second separation region 22 formed of n-type silicon carbide is formed. The conductivity type of the second separation region 22 is n type which is the same as that of the drift layer 20, and the n-type impurity concentration of the second separation region 22 may be equal to that of the drift layer 20, or may be higher or lower than that of the drift layer 20.

On surfaces of the adjacent first well regions 30, the second separation region 22 therebetween, and the respective source regions 40 inside these first well regions 30, the gate insulating film 50 formed of, for example, silicon oxide is selectively formed. On at least the gate insulating film 50 on the upper side of the first well region 30, the gate electrode 60 formed of, for example, polycrystalline silicon is formed. The surface layer portion of the first well region 30 facing the gate electrode 60 with the gate insulating film 50 interposed therebetween is referred to as the “channel region”.

On the outer side of the first well region 30 in the outermost perimeter of the silicon carbide semiconductor device 100, the second well region 31 is formed, and between the first well region 30 and the second well region 31, the third separation region 23 formed of silicon carbide is formed. The conductivity type of the third separation region 23 is n type which is the same as that of the drift layer 20, and the n-type impurity concentration of the third separation region 23 may be equal to that of the drift layer 20, or may be higher or lower than that of the drift layer 20.

The gate insulating film 50 is selectively formed on the second well region 31, like on the first well region 30, and on the gate insulating film 50, formed is the gate electrode 60 electrically connected to the gate electrode 60 formed on the first well region 30.

In a region at a certain ratio of the upper layer portion of the second well region 31, formed is the silicon carbide conductive layer 45 formed of silicon carbide, having an n-type impurity concentration higher than that of the drift layer 20 and a low resistance. The silicon carbide conductive layer 45 has a sheet resistance lower than that of the second well region 31 and forms the pn junction with the p-type second well region 31. The silicon carbide conductive layer 45 is formed, for example, across the width which is a half or more of the width in the cross (transverse) sectional direction of the second well region 31. A portion where the silicon carbide conductive layer 45 is formed at the width which is a half or more of the width in the cross sectional direction of the second well region 31 does not necessarily need to be provided in all the cross sections but may be provided in some of the cross sections.

Between the gate electrode 60 and the source electrode 80, formed is the interlayer insulating film 55 formed of, for example, silicon oxide. The gate electrode 60 and the gate wiring 82 above the second well region 31 are connected to each other through the gate contact hole 95 formed in the interlayer insulating film 55. Further, on the outer peripheral side of the second well region 31, i.e., on the opposite side of the first well region 30, formed is the JTE region 38 formed of p-type silicon carbide. The impurity concentration of the JTE region 38 is lower than that of the second well region 31. The FLR (Field Limiting Ring) may be formed, instead of the JTE region 38. Furthermore, the combination of the JTE region 38 and the FLR may be formed.

On the second well region 31 and the silicon carbide conductive layer 45, the field insulating film 51 having a film thickness larger than that of the gate insulating film 50 or the gate insulating film 50 is formed. In part of the gate insulating film 50 or the field insulating film 51 on the surface of the silicon carbide conductive layer 45, an opening, i.e., the terminal region contact hole 91 is formed. The silicon carbide conductive layer 45 and the source electrode 80 are ohmic-connected to each other through the ohmic electrode 72 positioned at the terminal portion on the lower side of the terminal region contact hole 91.

The terminal region contact hole 91 penetrates the gate insulating film 50 or the field insulating film 51 and the interlayer insulating film 55, to thereby make an ohmic connection between the silicon carbide conductive layer 45 and the source electrode 80 but not connect the second well region 31 and the source electrode 80. Further, the width of the silicon carbide conductive layer 45 is larger than the diameter or the width of the terminal region contact hole 91.

In the present first preferred embodiment, the second well region 31 is not directly ohmic-connected to the source electrode 80.

In the active region, the ohmic electrode 70, the Schottky electrode 71, and the contact region 35 are connected to the source electrode 80 on the interlayer insulating film 55 through the active region contact hole 90 penetrating the interlayer insulating film 55 and the gate insulating film 50.

On the back-surface side of the semiconductor substrate 10, formed is the drain electrode 84.

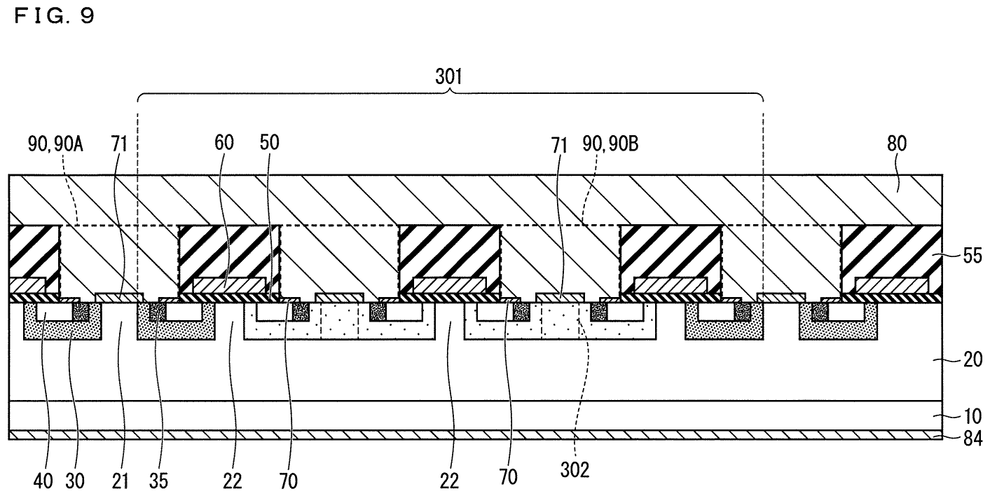

FIG. 9 is a schematic cross-sectional view showing a schematic structure of the surge energization region 301 and the active region contact hole 90. In this cross section, since the structure of the surge energization region 301 and the Schottky barrier diode replacement region 302 is the same as that shown in FIG. 6, detailed description will be omitted. Further, the area ratio of the Schottky barrier diode replacement region 302 in the active region 15 in a plan view is also the same as that described with reference to FIGS. 4 and 5.

### (3) Supplementary Explanation Common to Stripe and Lattice Structures

In a region of the active region, which is closest to the terminal region, an SBD high surface density structure, such as a folded structure or the like, may be formed. Further, in a region of the terminal region, which is closest to the active region, a terminal portion SBD high surface density structure including a JBS (Junction Barrier Schottky) in which many SBDs are formed may be formed. Furthermore, a sense cell for sensing a current may be provided inside the active region.

The n-type impurity concentration of the second separation region 22 may be higher than that of the drift layer 20. In a case where the drift layer 20 and the second separation region 22 are thus formed, an ON-resistance can be made lower.

### (4) Method of Manufacturing Planar Structure

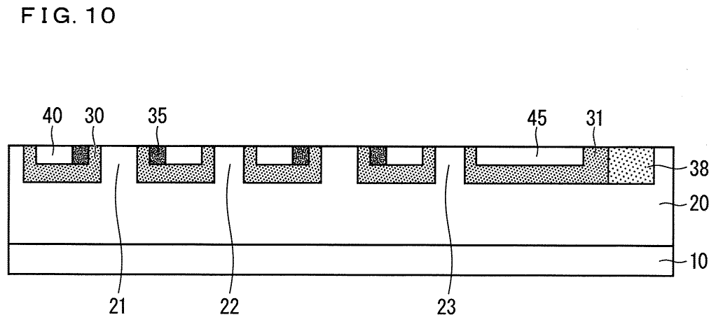

Next, a method of manufacturing the planar-type silicon carbide semiconductor device 100 in accordance with the first preferred embodiment will be described, with reference to the schematic cross-sectional views of FIGS. 10 to 17. Hereinafter, though a method of manufacturing the stripe-type silicon carbide semiconductor device 100 will be described, the same applies to a method of manufacturing the lattice-type silicon carbide semiconductor device 100.

First, the semiconductor substrate 10 formed of low-resistance n-type silicon carbide and having 4H polytype, in which the plane orientation of the first main surface is the (0001) plane having an off angle, is prepared. On the semiconductor substrate 10, the drift layer 20 formed of silicon carbide, having an n-type impurity concentration of, for example, 1×10¹⁵ to 1×10¹⁷ cm⁻³ and a thickness of, for example, 5 to 50 μm, is epitaxially grown by the chemical vapor deposition (CVD) method.

Subsequently, in a predetermined region of a surface of the drift layer 20, an implantation mask is formed of a photoresist or the like, and Al (aluminum) which is a p-type impurity is ion-implanted. At that time, the depth of the ion implantation of Al does not exceed the thickness of the drift layer 20 and is, for example, about 0.5 to 3 μm. Further, the impurity concentration of Al which is ion-implanted ranges, for example, from 1×10¹⁷ to 1×10¹⁹ cm⁻³, which is higher than the impurity concentration of the drift layer 20. After that, the implantation mask is removed. The region into which Al is ion-implanted in this process step becomes the first well region 30 in the active region and becomes the second well region 31 in the terminal region.

Next, in a predetermined region of the surface of the drift layer 20, the implantation mask is formed of a photoresist or the like, and Al which is a p-type impurity is ion-implanted. At that time, the depth of the ion implantation of Al does not exceed the thickness of the drift layer 20 and is, for example, about 0.5 to 3 μm. Further, the impurity concentration of Al which is ion-implanted ranges, for example, from 1×10¹⁷ to 1×10¹⁹ cm⁻³, which is higher than the impurity concentration of the drift layer 20. After that, the implantation mask is removed. The region into which Al is ion-implanted in this process step becomes the Schottky barrier diode replacement region 302.

Part of the surfaces of first well regions 30 adjacent to the Schottky barrier diode replacement region 302 become the channel region. In order to make a threshold voltage of first well regions 30 adjacent to the Schottky barrier diode replacement region 302 not lower than or preferably equal to that of the MOSFET region, the p-type impurity concentration of the surface of the Schottky barrier diode replacement region 302 and the adjacent first well regions 30 has only to be not lower than or preferably equal to that of the surface of the first well region 30 in the MOSFET region. As one method for achieving this, the implantation process for the Schottky barrier diode replacement region 302 and the adjacent first well regions 30 and that for the first well region 30 in the MOSFET region are performed as the same process step. By such a method, the p-type impurity concentrations of the surfaces of the Schottky barrier diode replacement region 302 and the first well region 30 can be made equal to each other and the number of process steps can be reduced.

Next, in a predetermined region of the surface of the drift layer 20 in the terminal region, the implantation mask is formed of a photoresist or the like, and Al which is a p-type impurity is ion-implanted. At that time, the depth of the ion implantation of Al does not exceed the thickness of the drift layer 20 and is, for example, about 0.5 to 3 μm. Further, the impurity concentration of Al which is ion-implanted ranges, for example, from 1×10¹⁶ to 1×10¹⁸ cm⁻³, which is higher than the impurity concentration of the drift layer 20 and lower than the impurity concentrations of the first well region 30 and the Schottky barrier diode replacement region 302. After that, the implantation mask is removed. The region into which Al is ion-implanted in this process step becomes the JTE region 38. Similarly, in a predetermined region of the surface layer portions of the first well region 30 and the Schottky barrier diode replacement region 302, by performing ion implantation of Al at an impurity concentration of, for example, 1×10¹⁶ to 1×10¹⁸ cm⁻³, which is higher than that of these regions, the contact region 35 is formed.

Subsequently, the implantation mask is formed of a photoresist or the like so as to expose a predetermined portion inside the surface layer portions of the first well region 30 and the Schottky barrier diode replacement region 302, and N (nitrogen) which is an n-type impurity is ion-implanted. The depth of the ion implantation of N is made shallower than the thickness of the first well region 30. Further, the impurity concentration of N which is ion-implanted ranges, for example, from 1×10¹⁸ to 1×10²¹ cm⁻³, which is higher than the p-type impurity concentrations of the first well region 30 and the Schottky barrier diode replacement region 302. An n-type region in the region into which N is ion-implanted in this process step becomes the source region 40. The thickness of the source region 40 has only to be smaller than that of the first well region 30.

Similarly, the implantation mask is formed of a photoresist or the like so as to expose a predetermined portion inside the second well region 31 in the terminal region, and N which is an n-type impurity is ion-implanted. The depth of the ion implantation of N is made shallower than the thickness of the second well region 31. Further, the impurity concentration of N which is ion-implanted ranges, for example, from 1×10¹⁸ to 1×10²¹ cm⁻³, which is higher than the p-type impurity concentration of the second well region 31. An n-type region in the region into which N is ion-implanted in this process step becomes the silicon carbide conductive layer 45. The thickness of the silicon carbide conductive layer 45 has only to be smaller than that of the second well region 31.

The silicon carbide conductive layer 45 and the source region 40 may be formed in the same process step, at the same thickness, and at the same impurity concentration, or may be formed in different process steps, at different thicknesses, and at different impurity concentrations.

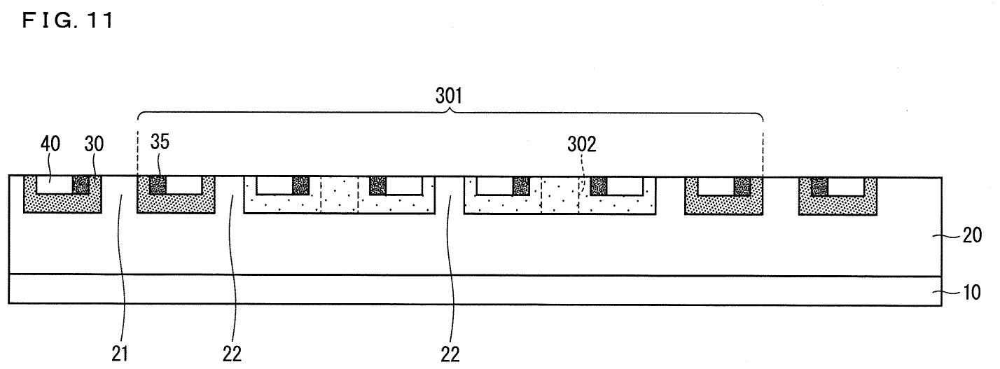

Next, in an inert gas atmosphere of argon (Ar) gas or the like, annealing is performed on the drift layer 20 by using a heat treatment apparatus, for example, at a temperature of 1300 to 1900° C. for 30 seconds to one hour. By this annealing, ion-implanted N and Al are electrically activated. FIGS. 10 and 11 are cross-sectional views showing the same region as shown in FIGS. 3 and 6, on which the process steps till this stage are completed.

Subsequently, by using the CVD method, the photolithography technique, or the like, the field insulating film 51 formed of silicon oxide is formed in a region other than the active region in which the first well region 30 and the surge energization region 301 are formed, i.e., on the terminal region. The film thickness of the field insulating film 51 is, for example, 0.5 to 2 μm and is larger than that of the gate insulating film 50.

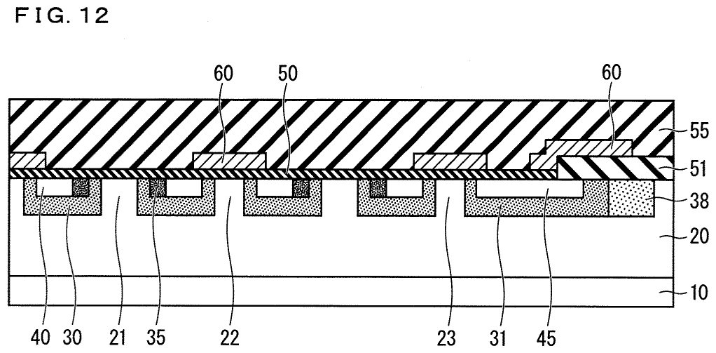

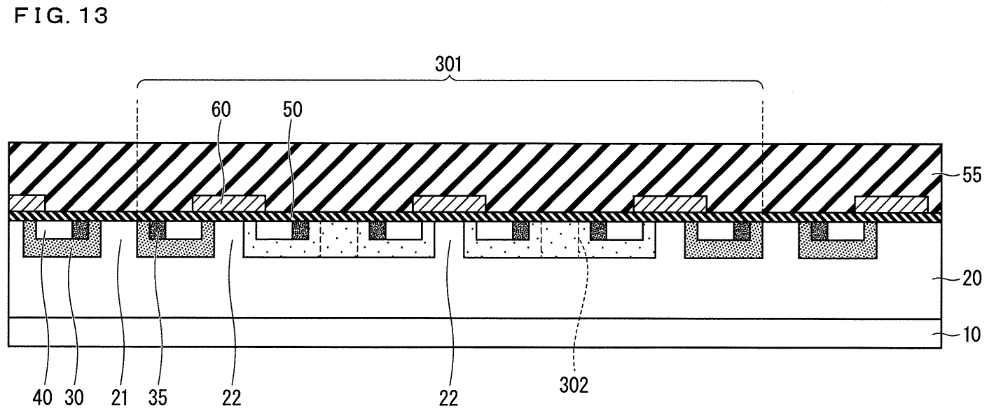

Next, a surface of the silicon carbide layer not covered with the field insulating film 51 is thermally oxidized, to thereby form a silicon oxide film having a desired thickness, as the gate insulating film 50. Subsequently, on the gate insulating film 50 and the field insulating film 51, for example, a polycrystalline silicon film having conductivity is formed by the low pressure CVD method and then patterned, to thereby form the gate electrode 60. Next, the interlayer insulating film 55 having a film thickness larger than that of the gate insulating film 50 and formed of, for example, silicon oxide is formed by the low pressure CVD method. FIGS. 12 and 13 are cross-sectional views showing the same region as shown in FIGS. 3 and 6, on which the process steps till this stage are completed.

Subsequently, part of the active region contact hole 90 which penetrates the interlayer insulating film 55 and the gate insulating film 50 and reaches the contact region 35 and the source region 40 inside the active region and the terminal region contact hole 91 which reaches the silicon carbide conductive layer 45 in the terminal region are formed. In the remaining part of the active region contact hole 90, i.e., a portion in which the Schottky electrode 71 is to be formed, however, the interlayer insulating film 55 and the gate insulating film 50 are left.

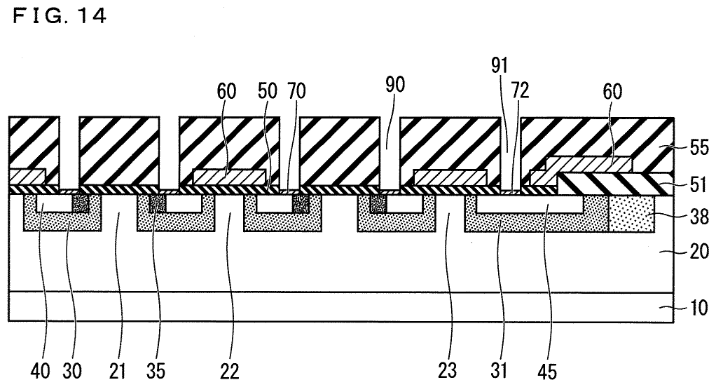

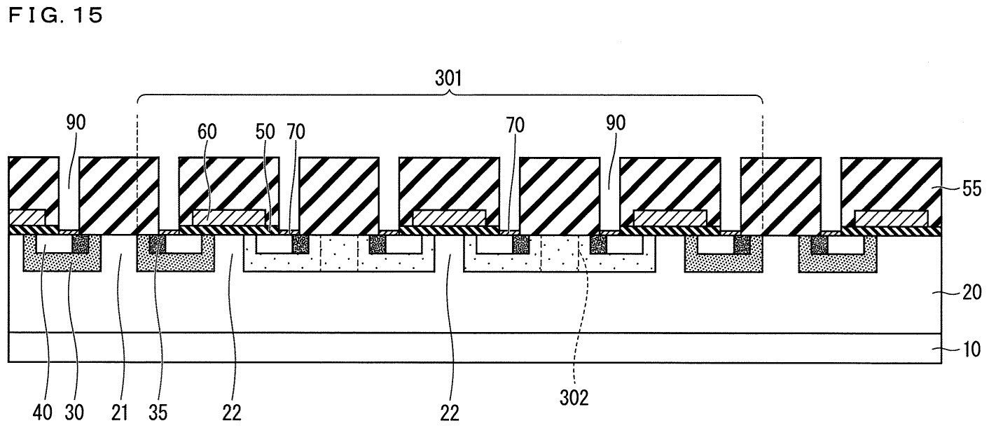

Next, on a surface of the silicon carbide layer exposed from part of the active region contact hole 90 and the terminal region contact hole 91, a metal film which is mainly formed of Ni (nickel) is formed by, for example, the sputtering method or the like, and then the heat treatment is performed at a temperature of 600 to 1100° C. By this operation, the metal film which is mainly formed of Ni and the silicon carbide layer react on each other, to thereby form a silicide layer between the metal film and the silicon carbide layer. Subsequently, the remaining metal film other than the silicide layer is removed by wet etching. By this operation, the remaining silicide layer becomes the ohmic electrode 70 and the ohmic electrode 72 at the terminal portion. FIGS. 14 and 15 are cross-sectional views showing the same region shown in FIGS. 3 and 6 on which the process steps till this stage are completed.

Subsequently, by forming a metal film which is mainly formed of Ni on the back surface (second main surface) of the semiconductor substrate 10 and performing a heat treatment thereon, the drain electrode 84 which is a back ohmic electrode is formed on the back side of the semiconductor substrate 10.

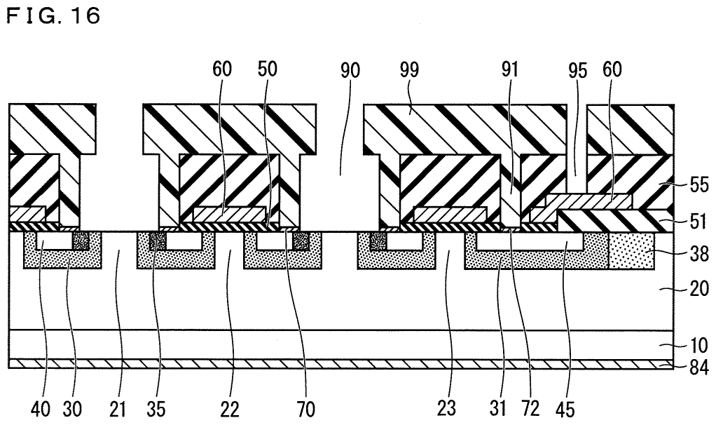

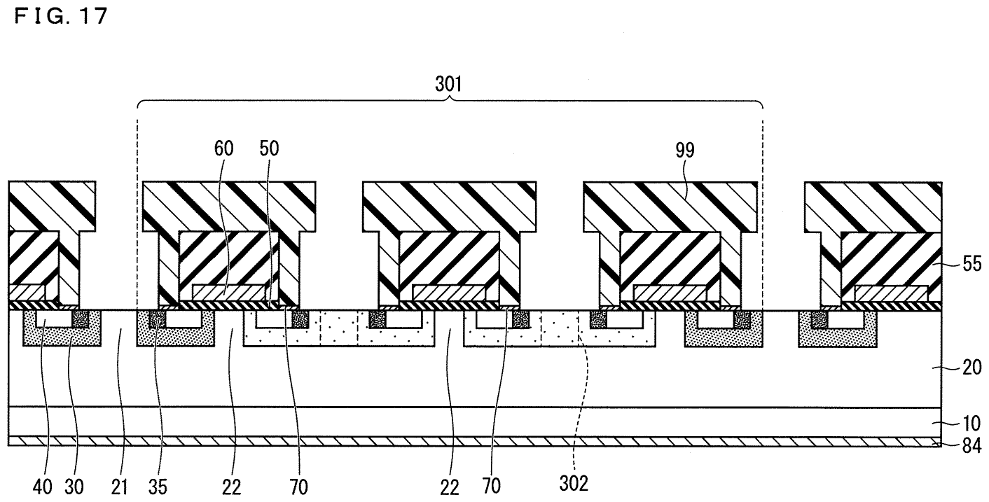

Next, a resist mask 99 is formed, and the interlayer insulating film 55 and the gate insulating film 50 on the first separation region 21 and the Schottky barrier diode replacement region 302 and the interlayer insulating film 55 to become the gate contact hole 95 are removed. As a method of removing the insulating films, used is a wet etching method which gives no damage on the surface of the silicon carbide layer serving as a Schottky interface. FIGS. 16 and 17 are cross-sectional views showing the same region shown in FIGS. 3 and 6 on which the process steps till this stage are completed.

Subsequently, after removing the resist mask 99, a metal film which is to become a Schottky electrode is deposited by the sputtering method or the like. Then, by using the patterning using a photoresist or the like, the Schottky electrode 71 is formed on the first separation region 21 and the Schottky barrier diode replacement region 302 inside the active region contact hole 90. The material of the Schottky electrode 71 is, for example, Ti (titanium), Mo (molybdenum), or the like.

Next, a wiring metal of Al or the like is formed on the surface of the substrate having been subjected to these treatments (process steps) till this stage by the sputtering method or the vapor deposition method and is processed into a predetermined shape by the photolithography technique, to thereby form the source electrode 80 in contact with the ohmic electrode 70 on the source side, the ohmic electrode 72 at the terminal portion, and the Schottky electrode 71, and the gate pad 81 and the gate wiring 82 which are in contact with the gate electrode 60. By the above-described process, manufactured is the silicon carbide semiconductor device 100 in accordance with the present first preferred embodiment shown in FIGS. 3 and 6.

### (5) Explanation of Operation

Next, an operation of the silicon carbide semiconductor device 100 in accordance with the present first preferred embodiment will be described. Herein, description will be made, taking the silicon carbide semiconductor device whose semiconductor material is 4H-type silicon carbide, as an example. The diffusion potential of the pn junction in this case is about 2 V.

The operation of the silicon carbide semiconductor device 100 in accordance with the present first preferred embodiment is divided into four normal operation states and one abnormal state, to be simply described.

The first normal operation state is a state in a case where a voltage applied to the drain electrode 84 is higher than that applied to the source electrode 80 and a positive voltage not lower than the threshold voltage is applied to the gate electrode 60, and this state is hereinafter referred to as an “ON state”. In this ON state, an inversion channel is formed in the channel region, and a path in which electrons as carriers are carried is formed between the n-type source region 40 and the n-type second separation region 22. On the other hand, in a Schottky junction formed in a contact portion between the first separation region 21 and the Schottky electrode 71, no current is carried since an electric field (reverse bias) in a direction in which a current is hard to flow for the Schottky connection, i.e., in a reverse direction is applied.

The electrons flowing into the drain electrode 84 from the source electrode 80 follow the electric field formed by the positive voltage applied to the drain electrode 84. For this reason, the electrons reach the drain electrode 84 from the source electrode 80 through the ohmic electrode 70, the source region 40, the channel region, the second separation region 22, the drift layer 20, and the semiconductor substrate 10. Therefore, by applying the positive voltage to the gate electrode 60, an ON-current is carried from the drain electrode 84 to the source electrode 80. A voltage applied between the source electrode 80 and the drain electrode 84 is referred to as an ON-voltage, and a value obtained by dividing the ON-voltage by the density of the ON-current is referred to as an “ON-resistance”. The ON-resistance is equal to the sum of resistances in the path in which the above-described electrons are carried. Since the product of the ON-resistance and the square of the ON-current corresponds to the energization loss that the MOSFET consumes during the energization, it is preferable that the ON-resistance should be low. In the present first preferred embodiment, the channel region is also formed inside the surge energization region 301. Therefore, the surge energization region 301 can also contribute to reduction in the ON-resistance.

The second normal operation state is a state in a case where a voltage applied to the drain electrode 84 is higher than that applied to the source electrode 80 and a voltage lower than the threshold voltage is applied to the gate electrode 60, and this state is hereinafter referred to as an “OFF state”. In this OFF state, since there is no inverted carrier, the ON-current does not flow and a high voltage applied to a load in the ON state is applied between the source electrode 80 and the drain electrode 84 in the MOSFET.

Since the electric field in the same direction as that in the “On state” is applied to the Schottky junction formed in the contact portion between the first separation region 21 and the Schottky electrode 71, ideally no current is carried. Since an electric field which is much higher than that in the “ON state” is applied, however, a leakage current can be generated. When the leakage current is large, there is a possibility that heat generation of the MOSFET may increase, to thereby cause thermal destruction of the MOSFET and a module using the MOSFET. For this reason, in order to reduce the leakage current, it is preferable that the electric field applied to the Schottky junction should be suppressed to be low.

The third normal operation state is a state in a case where a voltage applied to the drain electrode 84 is lower than that applied to the source electrode 80, i.e., a back electromotive voltage is applied to the MOSFET and a voltage lower than the threshold voltage is applied to the gate electrode 60. In this state, a circulating current is carried from the source electrode 80 toward the drain electrode 84. Hereinafter, this state is referred to as an “asynchronous rectification state”. In the asynchronous rectification state, in the active region other than the surge energization region 301, an electric field (forward bias) in a forward direction is applied to the Schottky junction formed in the contact portion between the first separation region 21 and the Schottky electrode 71. For this reason, a unipolar current including an electronic current is carried from the Schottky electrode 71 toward the n-type first separation region 21. In other words, the unipolar current is carried in the SBD including the Schottky electrode 71 and the first separation region 21. A circulating current component of the freewheeling diode is mainly this unipolar component.

Further, the source electrode 80 and the first well region 30 have the same potential with the ohmic electrode 70 on the source side interposed therebetween. As a result, the forward bias is applied also to the pn junction between the p-type first well region 30 and the drift layer 20. The pn junction is, however, formed in parallel with the above-described Schottky junction, and when the OFF state is changed to the asynchronous rectification state, since the Schottky junction in which the threshold voltage is lower turns on before the pn junction does, almost all the circulating current is carried into the Schottky junction and no circulating current is carried into the pn junction.

Also in a case where the voltage applied between the source and the drain exceeds the diffusion potential of the pn junction, a voltage obtained by subtracting a voltage drop caused by the unipolar current of the SBD in the drift layer 20 from the source-drain voltage is applied to the pn junction. For this reason, a high source-drain voltage can be applied while the pn junction does not turn on, and as a result, a high current can be carried by only the unipolar current.

Thus, by embedding the SBD therein, in the asynchronous rectification state, it is possible to suppress a forward current which is a bipolar current from being carried to the pn junction, i.e., the body diode which is the parasitic pn diode. When a starting point of a basal plane dislocation or the like is present in the pn junction in which the bipolar current is carried, there is a possibility that a crystal defect such as a stacking fault or the like may be extended by repeating the asynchronous rectification state. Since the crystal defect such as the stacking fault or the like blocks a current flowing in a thickness direction of the chip, there is a possibility that the ON-resistance may increase, to thereby cause an element failure by a thermal run away. Since the SBD is embedded in the silicon carbide semiconductor device 100 in accordance with the present first preferred embodiment, it is possible to suppress the bipolar current from flowing into the pn junction during the reflux and increase the reliability of the silicon carbide semiconductor device 100.

On the other hand, in the surge energization region 301, since the first separation region 21 connected to the Schottky electrode 71 is not present, the unipolar current is hard to flow in the asynchronous rectification state. The unipolar current flowing in the contact portion between the Schottky electrode 71 and the first separation region 21, which is formed around the surge energization region 301, is diffused in the drift layer 20 in a chip plane direction, and the unipolar current is thereby carried more or less also in the drift layer 20 inside the surge energization region 301. Since the current density thereof is small also for the active region other than the surge energization region 301, however, the bipolar current becomes easier to flow in the pn junction of the surge energization region 301 by low source-drain voltage, than in the active region other than the surge energization region 301.

When the bipolar current flows in the pn junction, there is a possibility that the crystal defect such as a stacking fault or the like may be extended, but since it is assumed that a sequence time of the asynchronous rectification state is short, ranging from several hundred nsec to several usec, extension of the crystal defect such as a stacking fault or the like is hard to occur. Further, in the present first preferred embodiment, the area ratio of the Schottky barrier diode replacement region 302 in the active region is not lower than 0.01% and lower than the area ratio of the SBD region, not being replaced with the Schottky barrier diode replacement region 302, in the active region 15, and more preferably not lower than 0.01% and not higher than 5%, being relatively low. For this reason, it is possible to reduce the possibility of degradation in the reliability due to extension of the crystal defect such as a stacking fault or the like. Further, when the area ratio is not higher than 5%, since the effect on chip electrical characteristics in a normal operation can be almost ignored, it is possible to suppress degradation in the electrical characteristics, such as conduction loss or the like, by the surge energization region 301.

The fourth normal operation state is a state in a case where a voltage applied to the drain electrode 84 is lower than that applied to the source electrode 80, i.e., a back electromotive voltage is applied to the MOSFET and a voltage not lower than the threshold voltage is applied to the gate electrode 60. In this state, the circulating current is carried from the source electrode 80 toward the drain electrode 84. Hereinafter, this state is referred to as a “synchronous rectification state”. In the synchronous rectification state, the unipolar current flowing in the channel is carried, as well as the unipolar current flowing in the Schottky electrode 71. In the present first preferred embodiment, the channel is formed not only in the MOSFET region but also in the surge energization region 301. Therefore, in the surge energization region 301, though there is no junction between the Schottky electrode 71 and the first separation region 21, the channel current becomes a bearer of the unipolar current and it is possible to suppress the pn junction from turning on. It is thereby possible to suppress concentration of heat generation on the surge energization region 301 in the synchronous rectification state.

In an inverter operation, for example, the sequence in the synchronous rectification state occupies about a half of a carrier cycle, and it is assumed that the time thereof is relatively long, such as ranging from several ten usec to several msec. This time is much longer than that in the asynchronous rectification state where it is assumed that the time is short, ranging from several hundred nsec to several usec. If a current continues to be carried in the pn diode for such a long time, heat is locally generated. Hereinafter, the reason for this will be described.

First, as compared with the unipolar current, the bipolar current has characteristics of causing modulation of conductivity and reducing a drift resistance. In a region where the bipolar current is carried, the resistance is reduced and a larger amount of current is carried than that in the region where only the unipolar current is carried. In the local region where the bipolar current is carried, positive feedback in which the temperature thereby rises, and further, the modulation of conductivity becomes stronger and current concentration occurs begins. As a result, there is a possibility that local heat generation may occur in the surge energization region 301 and the like and reliability degradation such as crack of an electrode junction portion, breakage of the gate insulating film, and the like may be caused. In contrast to this, in the present first preferred embodiment, the channel current is carried in the surge energization region 301 during the synchronous rectification state. For this reason, since the operation of the pn diode in the surge energization region 301 can be suppressed and local heat generation can be avoided, it is possible to achieve high reliability.

Finally, as the abnormal state, a state where a surge current flows between the source and the drain will be described. In this state, due to an inverter fault or the like, a current exceeding a rated current momentarily flows from the source toward the drain. In these many cases, assumed is a case where an OFF signal is applied to the gate, and energization of the channel does not occur. At that time, it is required that the chip is not broken down due to heat generation. An allowable current that does not cause any fault is referred to as a surge capability. In order to increase the allowable current, it is important that the surge current is carried at low resistance, to thereby reduce the heat generation of the chip. Further, the abnormal state occurs only in very rare cases such as occurrence of an accident (a fault) and/or the like, and since the frequency of occurrence is less, it is said that it is not necessary, in general, to think of the reliability degradation caused by the energization of the pn diode, such as extension of the crystal defect such as a stacking fault or the like.

The surge capability, however, should be increased. From the viewpoint of increasing the surge capability, the bipolar current which more easily causes the modulation of conductivity than the unipolar current is suitable for carrying the surge current at low resistance. In the surge energization region 301 in accordance with the present first preferred embodiment, since the first separation region 21 connected to the Schottky electrode 71 is not present, the unipolar current is hard to flow. For this reason, at the start of surge energization, in the surge energization region 301, the pn junction turns on while an energizing current in a region other than the surge energization region 301 is low, and bipolar energization starts. In this state, when the surge current transiently increases and reaches a large current exceeding the rated current, the bipolar current flowing from the surge energization region 301 further increases, and the holes in the drift layer 20 are diffused toward the active region around the surge energization region 301.

In a region to which the holes are diffused, the resistance of the drift layer 20 is reduced and the unipolar current density increases, and the parasitic pn diode (in other words, the body diode) or the like in the MOSFET turns on. Then, the holes are diffused to the drift layer 20 around the region, and further the body diode in the adjacent active region turns on. In other words, at the energization of the surge current, with the surge energization region 301 as a starting point, the body diodes therearound perform a chain reaction and operate one after another. Since the body diodes thus turn on over a wide range of the chip, the chip is brought into a bipolar energization state and generated energy is reduced by lower resistance due to the modulation of conductivity, and it is thereby possible to suppress heat generation in a case where a chip current is carried. In other words, since an allowable surge current can be increased, it is possible to increase the surge capability.

Thus, in the surge energization region 301, it is possible not only to increase a current which can be carried in the surge energization region 301 but also to change the characteristics over a wide range of the chip by a chain operation. For this reason, the area ratio of the surge energization region 301 in the active region may be low.

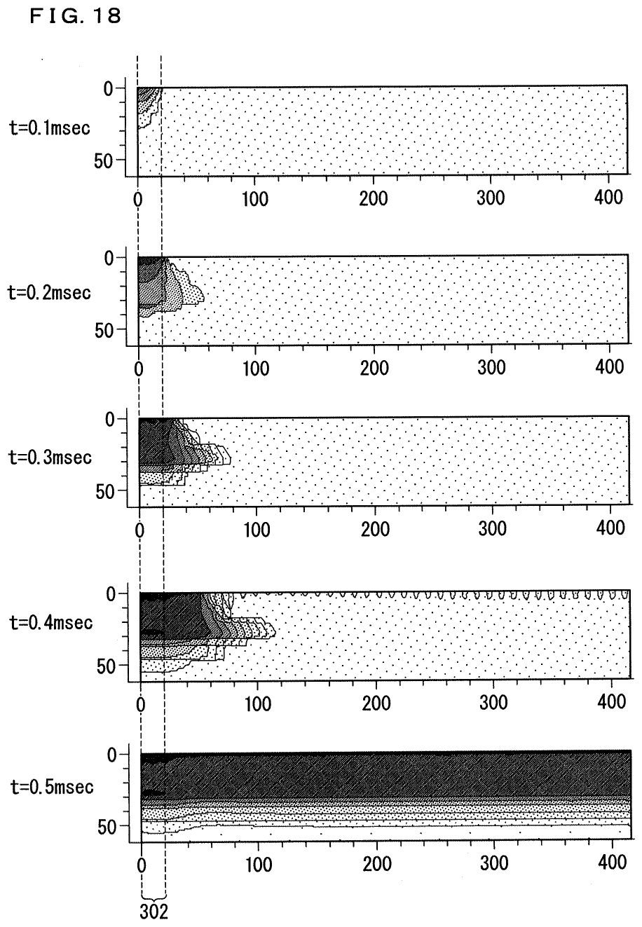

FIG. 18 is a view showing a result of verifying the chain operation of the pn diode from the Schottky barrier diode replacement region 302 having a width of 20 μm, by the TCAD (Technology Computer Aided Design) simulation. In FIG. 18, as the density of dots in dot hatching becomes higher, it means that hole concentration is higher. It is shown that as time passes, a body diode chain operation region which corresponds to a region in which the hole concentration is high spreads due to the modulation of conductivity of the bipolar energization. As described above, the body diode chain operation region is a region in which by a chain reaction with the operation of the pn diode of the Schottky barrier diode replacement region 302 as a starting point, the body diode which is the parasitic pn diode of the MOSFET in the unit cell region is operated.

After the pn diode in the surge energization region 301 is operated by the surge energization, it is confirmed that the hole density in an adjacent cell increases as time passes, the modulation of conductivity is propagated by the operation of the body diode which is the pn diode, and the body diode chain operation region spreads. By grasping the propagation speed of the pn diode operation at the surge current energization, i.e., the chain speed, the area ratio of the body diode chain operation region in the active region in a case where the surge energization not lower than 1 msec occurs, which is generally assumed to be the abnormal state, can be designed.

According to the present first preferred embodiment, as described above, as compared with the case where the surge energization region 301 is not present, the SBD energization is switched to the body diode energization at an early stage. Since the body diode which is the pn diode becomes low resistance due to the modulation of conductivity by the bipolar operation, the generated energy density is reduced at the same time as the start of the body diode energization. As a result, it is possible to suppress heat generation at the surge energization and increase the surge capability.

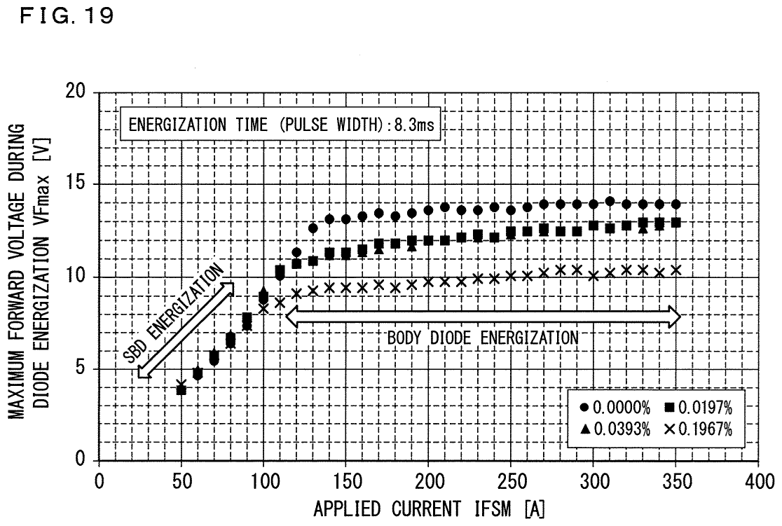

FIG. 19 is a graph showing a relation between a maximum forward voltage VFmax and an applied current IFSM at a surge energization test in a silicon carbide semiconductor device manufactured experimentally. In the silicon carbide semiconductor device manufactured experimentally, changed is the area ratio of the p-type Schottky barrier diode replacement region 302 of the surge energization region 301 in the active region 15 in a plan view.

As shown in FIG. 19, in a region where the current is relatively low, the SBD is energized, and when a certain or more amount of current is carried, the SBD energization is switched to the body diode energization and the gradient of V-I characteristics is changed due to the resistance change. At that time, as switching to the body diode energization is performed earlier, the generated energy is more reduced and this is advantageous for the surge capability. In FIG. 19, evaluation is made by changing the area ratio of the Schottky barrier diode replacement region 302 in the active region 15 in a plan view from about 0.0197% to 0.1967%. As a result, it is confirmed that as the area ratio becomes higher, a body diode operation start voltage is reduced and switching to the body diode energization becomes earlier.

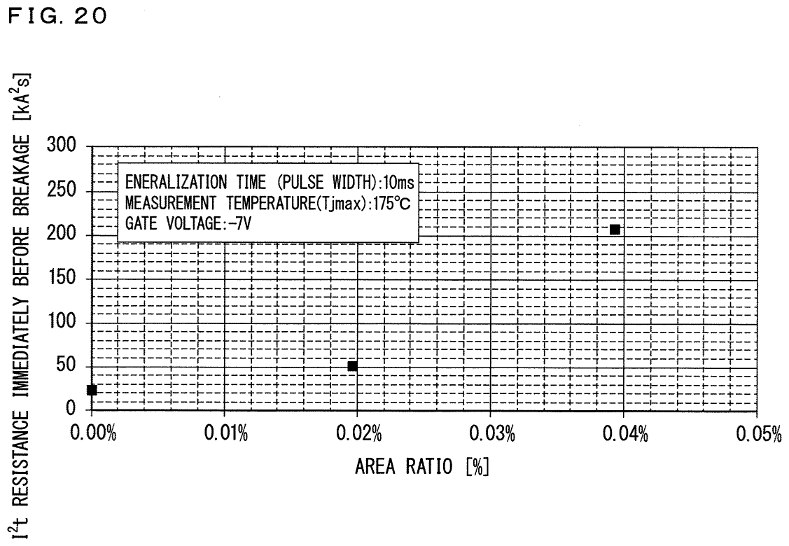

FIG. 20 is a graph showing a result of checking the surge capability on the basis of the above result. The surge current to be applied to the silicon carbide semiconductor device is gradually increased and the measurement is performed until breakage occurs in the silicon carbide semiconductor device. As a result, it is confirmed that as compared with the structure in which the Schottky barrier diode replacement region 302 is not present, the surge capability is improved in the structure having the Schottky barrier diode replacement region 302.

Further, in the present first preferred embodiment, at a position far away from the junction portion between the Schottky electrode 71 and the first separation region 21, the Schottky barrier diode replacement region 302 is connected to the source electrode 80 through the active region second contact hole 90B. In other words, inside the surge energization region 301, formed is the pn diode penetrating between the source and the drain in the chip cross-sectional direction. Since this pn diode does not need to carry a current inside a p-type layer having a high sheet resistance in the chip plane direction, when the pn diode turns on by the surge current, the pn diode can carry a large amount of bipolar current. For this reason, the Schottky barrier diode replacement region 302 is easy to function as the starting point of the pn diode operation.

Furthermore, in the present first preferred embodiment, since a unipolar transistor and a bipolar diode coexist inside the active region of the same chip, it is possible to reduce an effective area of the diode region, as compared with a case where one of them is provided outside.

Further, in order to further increase the surge capability, it is preferable that a plurality of surge energization regions 301 should be arranged uniformly over the entire active region so that regions in which the pn diodes are operated in a chain reaction from the surge energization region 301 should not be unevenly distributed. With such a structure, it is possible to disperse heat generation portions.

### The Second Preferred Embodiment

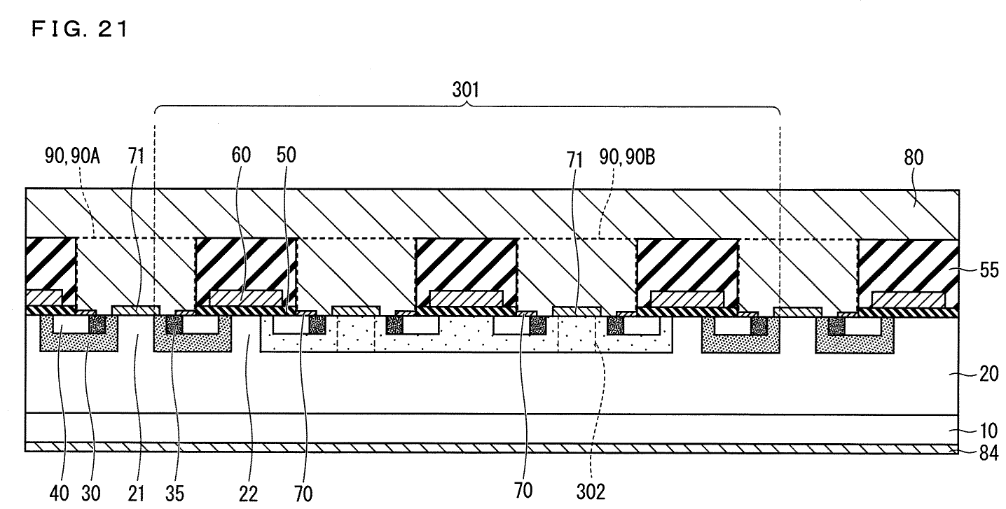

FIG. 21 is a schematic cross-sectional view showing a schematic structure of the surge energization region 301 and the active region contact hole 90 in accordance with the second preferred embodiment. As shown in FIG. 6, inside the surge energization region 301 in accordance with the first preferred embodiment, formed is the second separation region 22. In contrast to this, inside the surge energization region 301 in accordance with the present second preferred embodiment, the second separation region 22 is not formed as shown in FIG. 21. As an example of the layout method, inside the surge energization region 301, a region including the first well region 30, the first separation region 21, and the second separation region 22 is replaced with the p type.

With such a structure, since no channel is present in the surge energization region 301, the surge energization region 301 does not have any function of the MOSFET. For this reason, also in a case where the gate is turned on, since the pn diode preferentially turns on and the operation of the pn diode is chained to a surrounding region thereof, it is possible to increase the surge capability.

### Variation of the First and Second Preferred Embodiments

Though the unit cell structure in which the SBD region and the MOSFET region are unified is formed in the active region in the above description, the SBD and the MOSFET may be arranged in parallel inside the unit cell formed in the active region.

### The Third Preferred Embodiment

The silicon carbide semiconductor device 100 in accordance with the first or second preferred embodiment is a planar-type silicon carbide semiconductor device. In contrast to this, the silicon carbide semiconductor device 100 in accordance with the third preferred embodiment is a trench-type silicon carbide semiconductor device.

### (1) Trench Structure

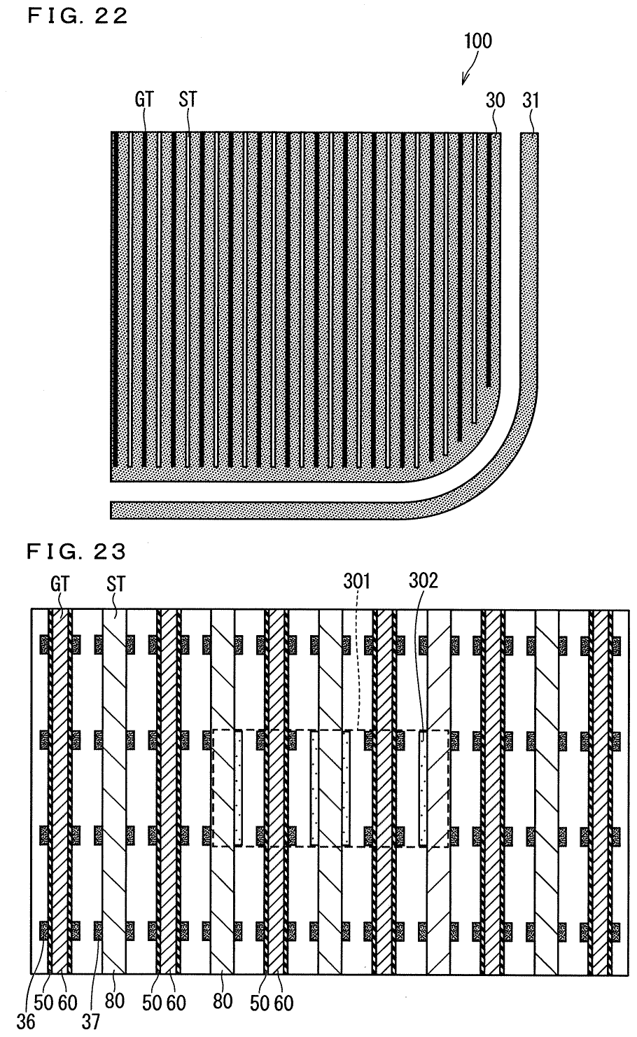

FIG. 22 is a plan view showing a silicon carbide layer of the silicon carbide semiconductor device 100 in accordance with the third preferred embodiment, viewed from the upper surface, and corresponds to the plan view of FIG. 2. In the silicon carbide semiconductor device 100 shown in FIG. 22, in the active region, stripe-shaped gate trenches GT on each of which a transistor is formed and stripe-shaped Schottky trenches ST in each of which the Schottky electrode is embedded are arranged alternately in parallel with each other. In the terminal region around the active region, the second well region 31 is formed.

FIG. 23 is an enlarged plan view showing the active region of the silicon carbide semiconductor device 100 in accordance with the third preferred embodiment. In the gate trench GT and the Schottky trench ST, first connection regions 36 and second connection regions 37, each of which is formed of p-type silicon carbide, are formed, respectively, adjacent to one another at regular intervals along the extension direction thereof. Further, inside the surge energization region 301, in the Schottky trench ST, the p-type Schottky barrier diode replacement region 302 is formed adjacent thereto. A region including the unit cell region including the Schottky trench ST substantially corresponding to the SBD region and the gate trench GT substantially corresponding to the MOSFET region, and the surge energization region 301, is referred to as the active region.

In the terminal region of the silicon carbide semiconductor device 100 in accordance with the third preferred embodiment, a structure like the planar-type silicon carbide semiconductor device 100 described in the first preferred embodiment and the like may be formed, or another structure in conformity with the trench type may be formed. Hereinafter, description will be made only on the active region of the silicon carbide semiconductor device 100 in accordance with the third preferred embodiment.

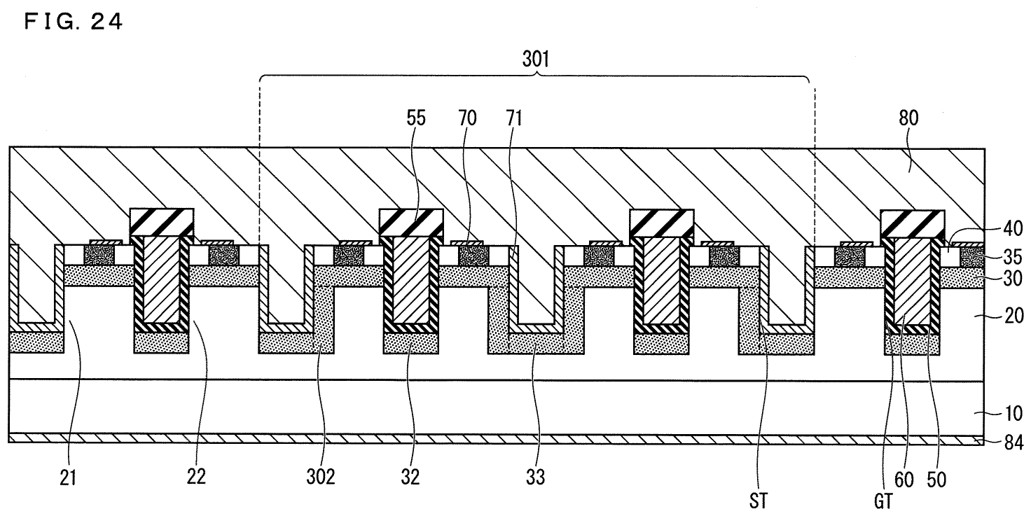

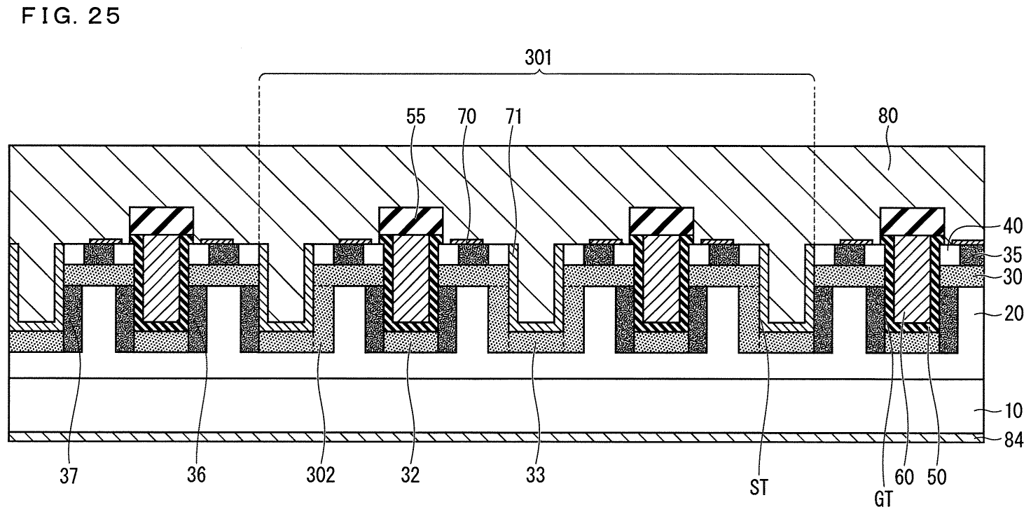

FIG. 24 is a schematic cross-sectional view schematically showing a portion in the active region including the surge energization region 301 shown in FIG. 23, in which neither the first connection region 36 nor the second connection region 37 are formed. FIG. 25 is a schematic cross-sectional view schematically showing a portion in the active region including the surge energization region 301 shown in FIG. 23, in which the first connection region 36 and the second connection region 37 are formed.

In the silicon carbide semiconductor device 100 shown in FIGS. 23 to 25, on the surface of the semiconductor substrate 10 formed of low-resistance n-type silicon carbide, the drift layer 20 formed of n-type silicon carbide is formed. In the present third preferred embodiment, though the semiconductor layer in which the active region is provided is the drift layer 20 on the semiconductor substrate 10, the semiconductor layer may be the semiconductor substrate 10. As shown in the cross-sectional views of FIGS. 24 and 25, in the surface layer portion of the drift layer 20, the first well region 30 formed of p-type silicon carbide is formed.

In part of the surface layer portion on the first well region 30, the source region 40 formed of n-type silicon carbide is formed. In the remaining surface layer portion on the first well region 30, the contact region 35 formed of low-resistance p-type silicon carbide is formed adjacent to the source region 40.

In the active region, formed is the gate trench GT penetrating the source region 40 and the first well region 30 and reaching the drift layer 20. Further, in another portion, formed is the Schottky trench ST penetrating the source region 40 and the first well region 30 and reaching the drift layer 20.

The gate trenches GT and the Schottky trenches ST are arranged alternately in parallel with each other. The gate trench GT and the Schottky trench ST have the same depth but may have different depths. Further, the gate trench GT and the Schottky trench ST may be formed to have the same width, or may be formed to have different widths.

Inside the gate trench GT, the gate electrode 60 is formed with the gate insulating film 50 formed of, for example, silicon oxide interposed therebetween. The gate electrode 60 is formed of, for example, low-resistance polycrystalline silicon having a high impurity concentration. On the gate electrode 60, formed is the interlayer insulating film 55 formed of, for example, silicon oxide. Inside the Schottky trench ST, formed are the Schottky electrode 71 and the source electrode 80, and the Schottky electrode 71 is formed in contact with the drift layer 20 and Schottky-connected to the drift layer 20.

Inside the drift layer 20 at the bottom of the gate trench GT, formed is the p-type first protection region 32. Inside the drift layer 20 at the bottom of the Schottky trench ST, formed is the p-type second protection region 33. It is preferable that the first protection region 32 and the second protection region 33 should have the same depth and have the same impurity concentration.

As shown in FIG. 25, the first protection region 32 and the first well region 30 are connected to each other with the p-type first connection region 36. Further, the second protection region 33 and the first well region 30 are connected to each other with the p-type second connection region 37.

On the surface of the source region 40, formed is the ohmic electrode 70. The source electrode 80 to be connected to the ohmic electrode 70, the Schottky electrode 71, and the contact region 35 is formed thereon. The first well region 30 can easily give and receive electrons or positive holes to/from the ohmic electrode 70 through the low-resistance contact region 35. The source electrode 80 is also connected to the Schottky electrode 71 inside the Schottky trench ST.

A region of the first well region 30, facing the gate electrode 60 with the gate insulating film 50 interposed therebetween, in a side surface of the gate trench GT in which the gate electrode 60 is formed is referred to as the channel region. On a portion in a side surface of the Schottky trench ST, in which the Schottky electrode 71 and the drift layer 20 are in contact with each other, the SBD is formed.

On the back-surface side of the semiconductor substrate 10, formed is the drain electrode 84.

Further, the second well region 31 in the terminal region may have the same depth and thickness as those of the first well region 30 in the active region. Furthermore, the second well region 31 in the terminal region may be formed up to the depth of the bottom of each of the gate trench GT and the Schottky trench ST so as to have the same depth as that of the first protection region 32 and the second protection region 33 in the active region. Further, the low-resistance n-type silicon carbide conductive layer 45 may be formed in the surface layer portion of the second well region 31. Furthermore, the second well region 31 may not be directly ohmic-connected to the source electrode 80.

As shown in FIG. 24, in the present third preferred embodiment, the first separation region 21 corresponds to a region which is in contact with the side surface of the Schottky trench ST and sandwiched between the first well region 30 and the second protection region 33 which are in contact with the Schottky trench ST. Further, the second separation region 22 corresponds to a region which is in contact with the side surface of the gate trench GT and sandwiched between the first well region 30 and the first protection region 32 which are in contact with the gate trench GT.

In the surge energization region 301, the first separation region 21 is replaced with the p-type Schottky barrier diode replacement region 302 which is in contact with the side surface of the Schottky trench ST. Further, in FIGS. 24 and 25, a boundary of the Schottky barrier diode replacement region 302 for convenience is indicated by the dotted line. The Schottky electrode 71 is not connected to the n-type silicon carbide layer such as the first separation region 21 or the like having n type like the drift layer 20, and the Schottky electrode 71 and the drift layer 20 are separated from each other by the p-type Schottky barrier diode replacement region 302.

Further, in the present third preferred embodiment, like in the first preferred embodiment, the area ratio of the Schottky barrier diode replacement region 302 in the active region 15 in a plan view is not lower than 0.01% and lower than the area ratio of the SBD region, not being replaced with the Schottky barrier diode replacement region 302, in the active region 15, and more preferably not lower than 0.01% and not higher than 5%.

### (2) Method of Manufacturing Trench Structure

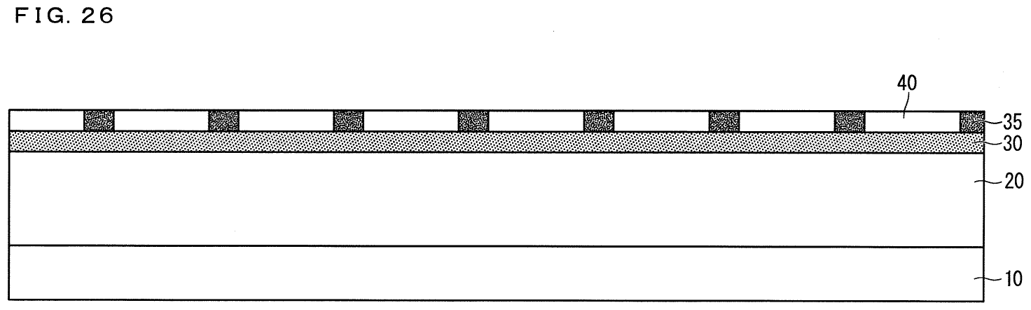

Next, a method of manufacturing the trench-type silicon carbide semiconductor device 100 in accordance with the third preferred embodiment will be described, with reference to the schematic cross-sectional views of FIGS. 26 to 31, showing the active region. Though description will be made herein on a method of manufacturing a portion in which the first connection region 36, the second connection region 37, or the Schottky barrier diode replacement region 302 is not formed, a portion in which these regions are formed is substantially the same as below and therefore will be described as appropriate without being shown.

First, the semiconductor substrate 10 formed of low-resistance n-type silicon carbide and having 4H polytype, in which the plane orientation of the first main surface is the (0001) plane having an off angle, is prepared. On the semiconductor substrate 10, the drift layer 20 formed of silicon carbide, having an n-type impurity concentration of, for example, 1×10¹⁵ to 1×10¹⁷ cm⁻³ and a thickness of, for example, 5 to 50 μm, is epitaxially grown by the chemical vapor deposition (CVD) method.

Subsequently, Al which is a p-type impurity is ion-implanted into the surface of the drift layer 20. At that time, the depth of the ion implantation of Al does not exceed the thickness of the drift layer 20 and is, for example, about 0.5 to 3 μm. Further, the impurity concentration of Al which is ion-implanted ranges, for example, from 1×10¹⁷ to 1×10¹⁹ cm⁻³, which is higher than the impurity concentration of the drift layer 20. The region into which Al is ion-implanted in this process step becomes the first well region 30 in the active region and becomes the second well region 31 in the terminal region. Furthermore, the first well region 30 may be formed on the drift layer 20 by the epitaxial growth method, instead of the ion implantation.

Next, in a predetermined region of the surface layer portion of the first well region 30, by performing ion implantation of Al at an impurity concentration of, for example, 1×10¹⁶ to 1×10¹⁸ cm⁻³, which is higher than that of the first well region 30, the contact region 35 is formed. Further, in a predetermined region of the surface layer portion of the first well region 30, N which is an n-type impurity is ion-implanted. The depth of the ion implantation of N is made shallower than the thickness of the first well region 30. Further, the impurity concentration of N which is ion-implanted ranges, for example, from 1×10¹⁸ to 1×10²¹ cm⁻³, which is higher than the p-type impurity concentration of the first well region 30. An n-type region in the region into which N is ion-implanted in this process step becomes the source region 40. FIG. 26 is a cross-sectional view showing the active region on which the process steps till this stage are completed.

Next, in one source region 40 between the adjacent contact regions 35, any one of the gate trench GT and the Schottky trench ST is formed. Further, the gate trenches GT and the Schottky trenches ST are arranged alternately. Al which is a p-type impurity is ion-implanted into the bottom of each of the gate trench GT and the Schottky trench ST. The first protection region 32 is thereby formed on the bottom of the gate trench GT and the second protection region 33 is thereby formed on the bottom of the Schottky trench ST. The impurity concentration of each of the first protection region 32 and the second protection region 33 is, for example, 1×10¹⁷ to 1×10¹⁹ cm⁻³.

The first connection region 36 and the second connection region 37 formed in the gate trench GT and the Schottky trench ST, respectively, are formed by, for example, performing oblique (tilt) ion implantation of the p-type impurity ions such as Al or the like from an orthogonal direction of a stretching direction of each trench. The impurity concentration of each of the first connection region 36 and the second connection region 37 is, for example, 1×10¹⁷ to 1×10¹⁹ cm⁻³.

Like the first connection region 36 and the second connection region 37, the Schottky barrier diode replacement region 302 is formed by, for example, performing oblique ion implantation of the p-type impurity ions such as Al or the like from the orthogonal direction of the stretching direction of the Schottky trench ST. The impurity concentration of the Schottky barrier diode replacement region 302 is 1×10¹⁷ to 1×10¹⁹ cm⁻³. By forming the Schottky barrier diode replacement region 302 at the same time as formation of at least one of the first connection region 36 and the second connection region 37, it is possible to reduce the number of process steps.

Herein, in a case where the plane orientation of the first main surface of the semiconductor substrate 10 is the (0001) plane having an off angle in the <11-20> direction, the extension direction of each of the gate trench GT and the Schottky trench ST in the active region may be parallel to the <11-20> direction which is an off-direction. With such a structure, since any effect in the off-direction of the semiconductor substrate 10 is not produced on the Schottky trench ST and trench sidewalls on both sides thereof, it is possible to reduce variation in the barrier height of the Schottky interface of the Schottky trench ST. Further, since any effect in the off-direction of the semiconductor substrate 10 is not produced on the threshold voltage of the MOSFET of the gate trench GT, it is possible to reduce variation in the threshold voltage of the MOSFET.

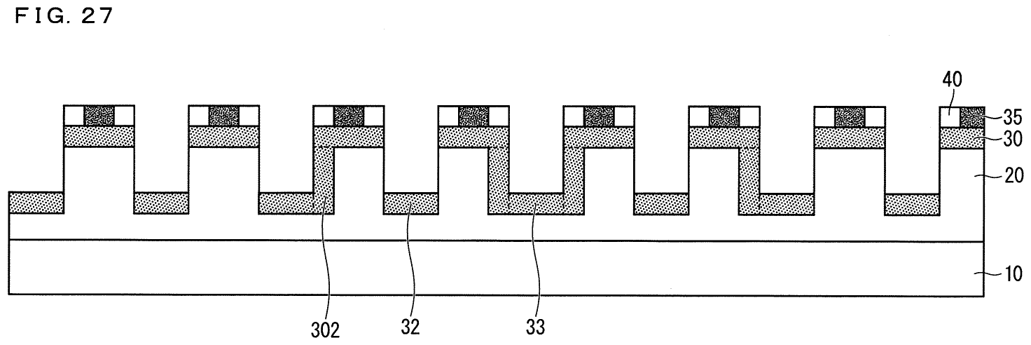

Subsequently, in the inert gas atmosphere of Ar gas or the like, annealing is performed on the drift layer 20 by using the heat treatment apparatus, for example, at a temperature of 1300 to 1900° C. for 30 seconds to one hour. By this annealing, ion-implanted N and Al are electrically activated. FIG. 27 is a cross-sectional view showing the active region on which the process steps till this stage are completed.

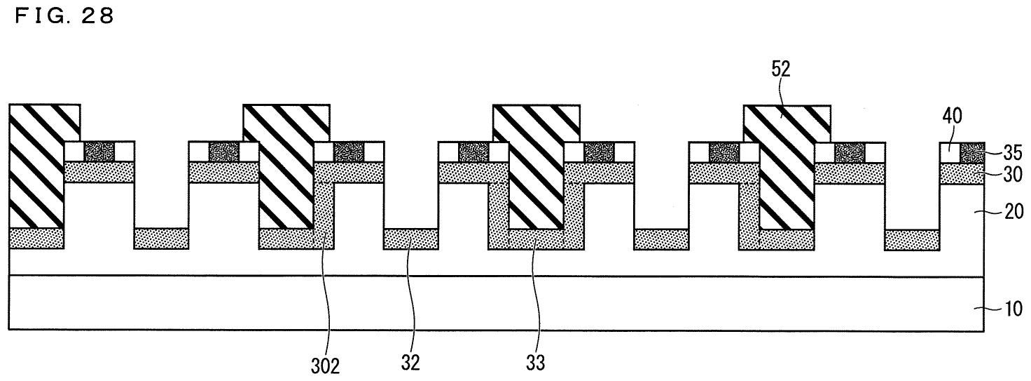

Subsequently, as shown in FIG. 28, the inside of the Schottky trench ST is filled with a protective insulating film 52 formed of, for example, silicon oxide.

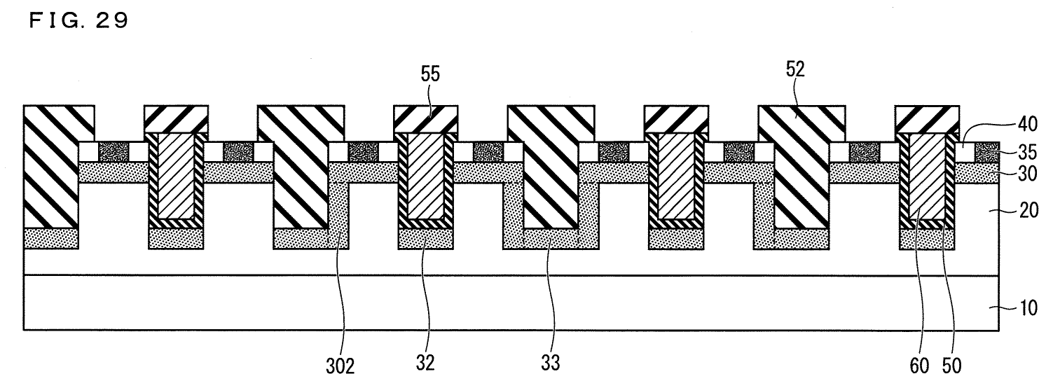

Next, a surface of the silicon carbide layer not covered with the protective insulating film 52 is thermally oxidized, to thereby form the gate insulating film 50 formed of, for example, silicon oxide and having a desired thickness inside the gate trench GT. Subsequently, on the gate insulating film 50, for example, the polycrystalline silicon film having conductivity is formed by the low pressure CVD method and then patterned, to thereby form the gate electrode 60. Next, on the gate electrode 60, the interlayer insulating film 55 having a film thickness larger than that of the gate insulating film 50 and formed of, for example, silicon oxide is formed by the low pressure CVD method. Subsequently, the interlayer insulating film 55 and the gate insulating film 50 are selectively removed by wet etching so as to expose the contact region 35 and the source region 40 in the active region. FIG. 29 is a cross-sectional view showing the active region on which the process steps till this stage are completed.

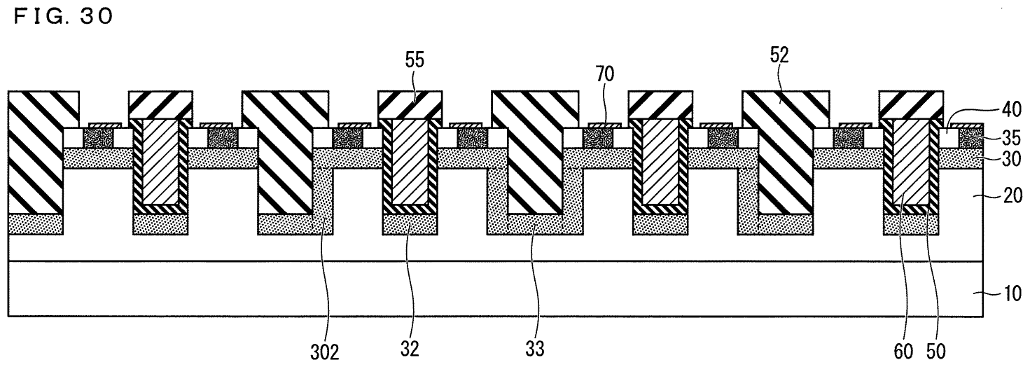

Subsequently, on the surfaces of the silicon carbide layers of the source region 40 and the contact region 35 which are exposed, a metal film which is mainly formed of Ni is formed by, for example, the sputtering method or the like, and then the heat treatment is performed at a temperature of 600 to 1100° C. By this operation, the metal film which is mainly formed of Ni and the silicon carbide layer react on each other, to thereby form a silicide layer between the metal film and the silicon carbide layer. Subsequently, the remaining metal film other than the silicide layer is removed by wet etching. By this operation, the remaining silicide layer becomes the ohmic electrode 70. FIG. 30 is a cross-sectional view showing the active region on which the process steps till this stage are completed.

Next, the protective insulating film 52 inside the Schottky trench ST is removed by using hydrofluoric acid or the like, and then the Schottky electrode 71 is formed inside the Schottky trench ST. The material of the Schottky electrode 71 is, for example, Ti, Mo, or the like.

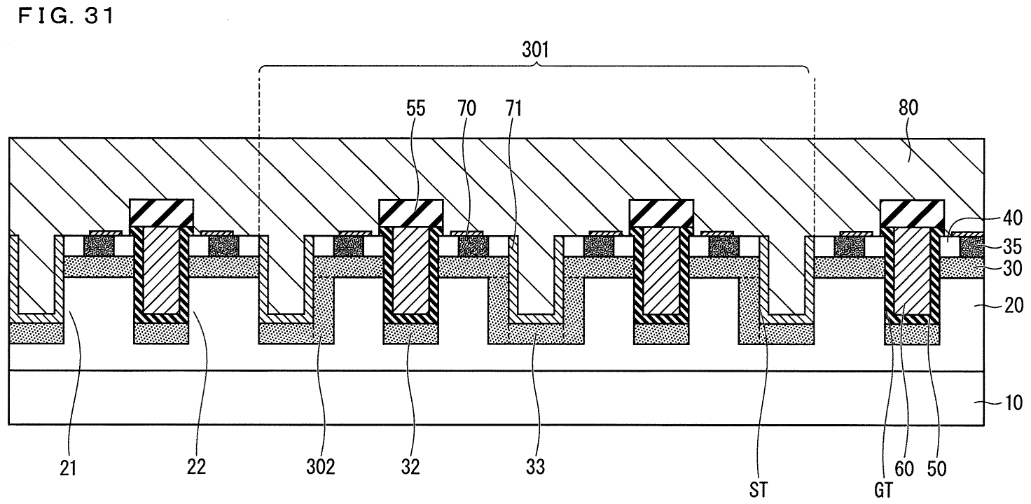

Subsequently, the source electrode 80 which is mainly formed of Al is formed, to be in contact with the Schottky electrode 71 and the ohmic electrode 70. FIG. 31 is a cross-sectional view showing the active region on which the process steps till this stage are completed. The gate pad 81 and the gate wiring 82 are formed in the same manner as the source electrode 80 is formed. The gate pad 81 and the gate wiring 82 may be formed at the same time as the source electrode 80 is formed.

Next, by forming a metal film which is mainly formed of Ni on the back surface of the semiconductor substrate 10 and performing a heat treatment thereon, the drain electrode 84 which is a back ohmic electrode is formed on the back side of the semiconductor substrate 10. Thus, the silicon carbide semiconductor device 100 in accordance with the third preferred embodiment shown in FIG. 24 is manufactured.

### (3) Explanation of Operation

Since the operation and the effect of the trench-type silicon carbide semiconductor device 100 in accordance with the third preferred embodiment are the same as those of the planar-type silicon carbide semiconductor device 100 in accordance with the first or second preferred embodiment, detailed description will be omitted.

### The Fourth Preferred Embodiment

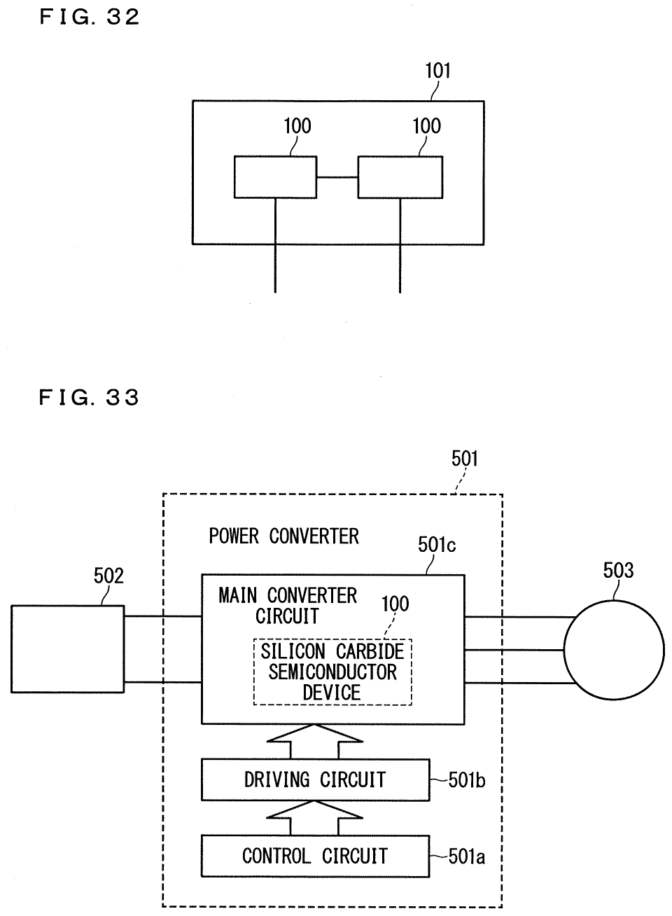

FIG. 32 is a block diagram schematically showing a structure of a power module device 101 in accordance with the fourth preferred embodiment. The power module device 101 includes a plurality of silicon carbide semiconductor devices 100 each of which is the silicon carbide semiconductor device 100 in accordance with any one of the first to fourth preferred embodiments.

With such a structure, it is possible to increase the surge capability of the power module device 101 at the energization of the surge current. Further, in the power module device 101, since the time from detection of the surge current to cut-off thereof can be ensured longer, it is possible to increase the degree of design freedom of a not-shown surge protection circuit operating at the energization of the surge current.

Further, in order to increase the current that the power module device 101 processes, the plurality of silicon carbide semiconductor devices serving as a switching element and a freewheeling diode may be connected in parallel to one another. These plurality of silicon carbide semiconductor devices may include the silicon carbide semiconductor device 100 having the surge energization region 301 and a silicon carbide semiconductor device not having the surge energization region 301. In order to prevent the phenomenon, however, that the pn diode of a specific silicon carbide semiconductor device turns on when the surge current is carried and the current is concentrated on the silicon carbide semiconductor device, the plurality of silicon carbide semiconductor devices may include only the silicon carbide semiconductor device 100.

### The Fifth Preferred Embodiment

FIG. 33 is a block diagram showing a power converter 501 in accordance with the fifth preferred embodiment. The power converter 501 includes a control circuit 501a, a driving circuit 501b, and a main converter circuit 501c equipped with the silicon carbide semiconductor device 100 in accordance with any one of the first to fourth preferred embodiments. Further, the main converter circuit 501c may be equipped with the power module device 101 in accordance with the fourth preferred embodiment, instead of the silicon carbide semiconductor device 100 in accordance with any one of the first to fourth preferred embodiments.

The driving circuit 501b drives the silicon carbide semiconductor device 100 of the main converter circuit 501c on the basis of a control signal from the control circuit 501a. The driving circuit 501b turns on the gate of the MOSFET of the silicon carbide semiconductor device 100 when the circulating current is carried to the parasitic pn diode which is the freewheeling diode of the silicon carbide semiconductor device 100, except a dead time for a short time. With such a structure, it is possible to carry the unipolar current through the channel and avoid concentration of heat generation in the surge energization region 301.

The control circuit 501c including the silicon carbide semiconductor device 100 converts the electric power from a power supply 502 into the electric power usable in a load 503. by driving of the silicon carbide semiconductor device 100 on the basis of the control signal.

With the above-described structure, it is possible to increase the surge capability in the power converter 501 at the energization of the surge current. Further, in the power converter 501, since the time from detection of the surge current to cut-off thereof can be ensured longer, it is possible to increase the degree of design freedom of a not-shown surge protection circuit operating at the energization of the surge current.

Further, in the present fifth preferred embodiment, since the silicon carbide semiconductor device 100 in accordance with any one of the first to fourth preferred embodiments is used as the switching element of the main converter circuit 501c, it is possible to achieve a power converter 501 in which the loss is low and the reliability of the high-speed switching is increased.

### The Sixth Preferred Embodiment

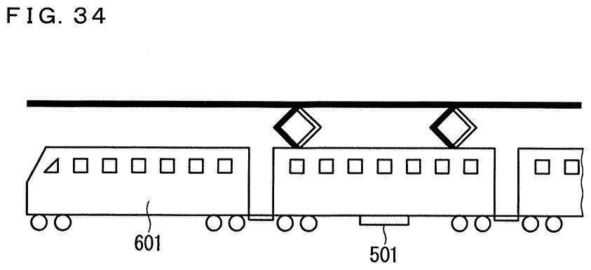

FIG. 34 is a view showing a mobile body 601 in accordance with the sixth preferred embodiment. Though the mobile body 601 is a train in the exemplary case of FIG. 34, the mobile body 601 is not limited to this example. The mobile body 601 is provided with the power converter 501 in accordance with the fifth preferred embodiment, and the power converter 501 generates electric power needed by the mobile body 601. With such a structure, it is possible to produce the same effect as that of the power converter 501 in accordance with the fifth preferred embodiment also on the power converter used in the mobile body 601.

### Supplementary Explanations on the First to Sixth Preferred Embodiments

The p-type impurity described above may be boron (B) or gallium (Ga), instead of aluminum (Al). The n-type impurity described above may be phosphorus (P), instead of nitrogen (N). The gate insulating film 50 described above does not necessarily need to be an oxide film such as SiO₂ or the like, but may be an insulating film other than the oxide film or a combination of the insulating film other than the oxide film and the oxide film. Further, the gate insulating film 50 may be a deposited film formed of silicon oxide which is formed by the CVD method, instead of silicon oxide obtained by the thermal oxidation of silicon carbide. Furthermore, in the above description, though the crystal structure, the plane orientation of the main surface, the off angle, the ion implantation conditions, and the like are described by using specific examples, these numerical ranges are only examples. Further, the silicon carbide semiconductor device 100 may have a structure in which the SBD is embedded in the MOSFET having a superjunction structure.

Further, the preferred embodiments and variations may be freely combined, or may be changed or omitted as appropriate.

The foregoing description is in all aspects illustrative and not restrictive. It is therefore understood that numerous modifications and variations which are not illustrated can be devised.

### EXPLANATION OF REFERENCE SIGNS

15 active region, 16 body diode chain operation region, 20 drift layer, 100 silicon carbide semiconductor device, 101 power module device, 301 surge energization region, 302 Schottky barrier diode replacement region, 501 power converter, 551 mobile body

1. A silicon carbide semiconductor device, comprising:
a semiconductor layer of a first conductivity type which is provided with an active region which includes a unit cell region including a Schottky barrier diode region partially having the first conductivity type and a MOSFET region, and a surge energization region,
wherein the surge energization region includes a Schottky barrier diode replacement region in which the first conductivity type of the Schottky barrier diode region is replaced with a second conductivity type, and
an area ratio of the Schottky barrier diode replacement region in the active region is not lower than 0.01% and lower than an area ratio of the Schottky barrier diode region in the active region in a case where the Schottky barrier diode region is not replaced with the Schottky barrier diode replacement region.

2. The silicon carbide semiconductor device according to claim 1, wherein
the surge energization region has a function of the MOSFET.

3. The silicon carbide semiconductor device according to claim 1, wherein
the surge energization region does not have a function of the MOSFET.

4. The silicon carbide semiconductor device according to claim 1, wherein
an area ratio of the Schottky barrier diode replacement region in the active region is not lower than 0.01% and not higher than 5%.

5. A power module device, comprising:
a plurality of silicon carbide semiconductor devices each of which is the silicon carbide semiconductor device according to claim 1.

6. A power converter for converting electric power by using a power module device which includes the silicon carbide semiconductor device according to claim 1.

7. A mobile body provided with the power converter according to claim 6.
